(19) United States
(12) Patent Application Publication
(10) Pub. No.: US 2026/0271234 A1
(43) Pub. Date: Sep. 10, 2026

(54) TRIPLY PERIODIC MINIMAL SURFACES FOR BOILING HEAT TRANSFER

(71) Applicant: The Chinese University of Hong Kong, Shatin (CN)

(72) Inventors: Dongyan XU, Shatin (CN); Xu SONG, Shatin (CN); Xiaotong WANG, Shatin (CN); Junhao DING, Shatin (CN); Zhe YAN, Shatin (CN); Jiyu HUA, Shatin (CN)

(21) Appl. No.: 19/555,693

(22) Filed: Mar. 3, 2026

Related U.S. Application Data
(60) Provisional application No. 63/767,847, filed on Mar. 6, 2025.

(51) Int. Cl. H05K 7/20

(52) U.S. Cl. CPC H05K 7/20327; H05K 7/20318; H05K 7/20409; H05K 7/20772

(57) ABSTRACT

Embodiments include a cooling structure for boiling heat transfer. The cooling structure may include a substrate. The substrate may be a fixed heat source or configured to be in thermal communication with the fixed heat source. The cooling structure may include a lattice disposed on the substrate. The lattice may include a plurality of triply periodic minimal surface (TPMS) unit cells. The TPMS unit cells may include surfaces that are periodic in a first direction, a second direction, and a third direction. Embodiments may include cooling systems with the cooling structure. Embodiments may include methods of manufacturing the cooling structure. Embodiments may include methods of using the cooling structure in boiling heat transfer.

### CROSS-REFERENCE TO RELATED APPLICATION

This application claims the benefit of priority to U.S. Provisional Patent Application No. 63/767,847, entitled “TRIPLY PERIODIC MINIMAL SURFACES FOR POOL BOILING HEAT TRANSFER,” filed on Mar. 6, 2025, the entire contents of which are incorporated herein for all purposes.

### BACKGROUND

Recent advances in artificial intelligence (AI), 5G technology, and internet of things (IoT) have led to an enormous increase in the usage and power consumption for data centers, which in turn poses a grand challenge for cooling technologies. Boiling heat transfer holds a great potential for cooling high-power-density electronic chips as it can dissipate a substantial amount of heat under a relatively small temperature difference owing to the large latent heat.

Boiling heat transfer can be a highly efficient mechanism for dissipating heat in power generation, electronics cooling, chemical processing, and other industrial applications. In pool boiling, a heated surface submerged in a saturated liquid causes the formation of vapor bubbles, facilitating energy transfer through latent heat. The efficiency of this process depends on factors such as surface characteristics, and fluid properties.

Boiling heat transfer occurs in distinct regimes, including natural convection, nucleate boiling, transition boiling, and film boiling. Among these, nucleate boiling is the desirable for efficient heat dissipation, as vapor bubbles form and detach rapidly, promoting high heat flux. However, as heat flux increases, the process reaches a critical heat flux (CHF) limit, beyond which excessive vapor formation leads to the formation of an insulating vapor layer, reducing heat transfer efficiency and potentially causing surface burnout.

In the past decades, high critical heat flux (CHF) and high heat transfer coefficient (HTC) have been pursued for high cooling efficiency through tuning micro/nanostructures and wettability of the boiling surfaces. Existing solutions often suffer from limitations such as manufacturing complexity, durability concerns, and scalability issues. Despite extensive efforts and remarkable performance enhancement, it remains challenging to design and manufacture micro/nanostructured boiling surfaces that can meet the future cooling demand of electronic industry and other industries.

### BRIEF SUMMARY

Embodiments described herein include triply periodic minimal surfaces (TPMS) for boiling heat transfer. The TPMS structures may be fabricated by additive manufacturing processes. Cooling structures with TPMS structures may be characterized by superior critical heat fluxes and heat transfer coefficients. Cooling structures may be used to cool microprocessors in data centers.

Embodiments include a cooling structure for boiling heat transfer. The cooling structure may include a substrate. The substrate may be a fixed heat source or configured to be in thermal communication with the fixed heat source. The cooling structure may include a lattice disposed on the substrate. The lattice may include a plurality of triply periodic minimal surface (TPMS) unit cells. The TPMS unit cells may include surfaces that are periodic in a first direction, a second direction, and a third direction.

Embodiments may include a cooling system. The cooling system may include the cooling structure. The cooling system may include a heat source. The cooling system may include a liquid in contact with the cooling structure.

Embodiments include a method of cooling. The method may include heating a cooling structure submerged in a liquid to a temperature sufficient to initiate nucleate boiling. Vapor may form at nucleation sites on the heated surface. The cooling structure may be any cooling structure described herein. The method may further include maintaining a heat flux at or below a critical heat flux of the cooling structure.

Embodiments include a method of manufacturing a cooling structure. The method may include providing a substrate. The substrate may be configured to be a fixed heat source during operation. The method may include depositing a lattice on the substrate. The lattice may include a plurality of triply periodic minimal surface (TPMS) unit cells. The TPMS unit cells may include surfaces that are periodic in a first direction, a second direction, and a third direction.

### Terms

“TPMS” refers to triply periodic minimal surfaces. TPMS may refer to a class of 3D structures characterized by a zero value of mean curvature at each point. They may be periodic in three dimensions, and the surface energy may be locally minimized.

“About” or “approximately” can mean within an acceptable error range for the particular value as determined by one of ordinary skill in the art, which will depend in part on how the value is measured or determined, i.e., the limitations of the measurement system. For example, “about” can mean within 1 or more than 1 standard deviation, per the practice in the art. Alternatively, “about” can mean a range of up to 20%, up to 10%, up to 5%, or up to 1% of a given value. Alternatively, particularly with respect to biological systems or processes, the term “about” or “approximately” can mean within an order of magnitude, within 5-fold, and more preferably within 2-fold, of a value. Where particular values are described in the application and claims, unless otherwise stated the term “about” meaning within an acceptable error range for the particular value should be assumed. The term “about” can have the meaning as commonly understood by one of ordinary skill in the art. The term “about” can refer to ±10%. The term “about” can refer to ±5%. Any exact number described herein may be modified with “about” or “approximately.”

### BRIEF DESCRIPTION OF THE DRAWINGS

To easily identify the discussion of any particular element or act, the most significant digit or digits in a reference number refer to the figure number in which that element is first introduced.

FIG. 1 illustrates a schematic diagram of a TPMS boiling heat transfer surface according to embodiments.

FIG. 2 illustrates examples of TPMS structures according to embodiments.

FIG. 3 illustrates a schematic diagram of implicit modelling of a functionally graded TPMS structure according to embodiments.

FIG. 4A illustrates a schematic diagram of a boiling heat transfer surface with the primitive (P) type TPMS structures according to embodiments.

FIG. 4B illustrates a schematic diagram of a boiling heat transfer surface with the gyroid (G) type TPMS structures according to embodiments.

FIG. 4C illustrates a schematic diagram of a boiling heat transfer surface with the diamond (D) type TPMS structures according to embodiments.

FIG. 5 illustrates a pool boiling experimental setup according to embodiments.

FIG. 6 illustrates a heating device according to embodiments.

FIG. 7A illustrates pool boiling curves according to embodiments.

FIG. 7B illustrates pool boiling heat transfer coefficient curves according to embodiments.

FIG. 8 illustrates pool boiling critical heat fluxes and heat transfer coefficients for the P, G, and D types TPMS structures with different unit cell sizes according to embodiments.

FIG. 9 illustrates unit cell phases for the D type TPMS structures according to embodiments.

FIG. 10 illustrates pool boiling critical heat fluxes and heat transfer coefficients for the D type TPMS structures with different unit cell phases according to embodiments.

FIGS. 11A-11C illustrate the effect of structure height on pool boiling CHF and HTC for different unit cell types with the unit cell size fixed at 1.5 mm according to embodiments.

FIG. 12 illustrates schematics of a D-type TPMS structure with a vertically graded unit cell size according to embodiments.

FIGS. 13A-13C show the effect of vertical gradient factor on the pool boiling CHF and HTC of D-type TPMS structures with the bottom unit cell size fixed at 1.5 mm at different heights according to embodiments.

FIG. 14 is a graph of the effect of the D-G blending ratio in TPMS structures on pool boiling CHF and HTC according to embodiments.

FIGS. 15A-15C illustrate the effects of the vertical gradient factor on pool boiling CHF and HTC for the blended structure (25% D and 75% G) with the bottom unit cell size fixed at 1.5 mm at different heights according to embodiments.

FIG. 16 is a graph comparing critical heat fluxes achieved by P, G, D, and vertically graded D types TPMS structured surfaces according to embodiments with counterparts of micro-/nanostructured boiling surfaces in the literature.

FIG. 17 illustrates a schematic diagram of the application of TPMS structured boiling surfaces in two-phase immersion cooling according to embodiments.

FIG. 18A illustrates the schematics of a flow boiling experimental setup according to embodiments.

FIG. 18B illustrates the components of the testing section according to embodiments.

FIG. 19 illustrates flow boiling heat transfer performance of three TPMS structured surfaces (P, G, and D) with a unit cell size of 1.5 mm and a structure height of 2 mm at a volumetric flow rate of 140 mL/min according to embodiments.

FIG. 20 illustrates flow boiling heat transfer performance of three TPMS structured surfaces (P, G, and D) with a unit cell size of 1.5 mm and a structure height of 2 mm at a volumetric flow rate of 260 mL/min according to embodiments.

FIG. 21 illustrates effects of unit cell size on flow boiling CHF and HTC at a volumetric flow rate of 140 mL/min according to embodiments.

FIG. 22 illustrates effects of unit cell size on flow boiling CHF and HTC at a volumetric flow rate of 260 mL/min according to embodiments.

FIG. 23 illustrates effects of structure height on flow boiling CHF and HTC at a volumetric flow rate of 140 mL/min according to embodiments.

FIG. 24 illustrates effects of structure height on flow boiling CHF and HTC at a volumetric flow rate of 260 mL/min according to embodiments.

FIG. 25 illustrates bubble removal in flow boiling according to embodiments.

FIG. 26 illustrates effects of vertical gradient factor on flow boiling CHF and HTC of D-type TPMS structures with different heights at a volumetric flow rate of 140 mL/min according to embodiments.

FIG. 27 illustrates effects of vertical gradient factor on flow boiling CHF and HTC of D type TPMS structures with different heights at a volumetric flow rate of 260 mL/min according to embodiments.

FIG. 28 illustrates the effects of the horizontal gradient factor on the flow boiling CHF and HTC of D-type TPMS structures according to embodiments.

FIG. 29 is a comparison of CoP and maximum heat flux achieved by TPMS structured surfaces according to embodiments with other boiling surfaces in literature.

FIG. 30 illustrates a method according to embodiments.

FIG. 31 illustrates a method according to embodiments.

### DETAILED DESCRIPTION

Recently, the rise of artificial intelligence (AI), 5G communication technology, and internet of things (IoT) has increased the demand for computing power across industries, thereby leading to cooling challenges for data centers. Compared to air cooling commonly used in data centers, liquid cooling, especially two-phase immersion cooling and direct-to-chip cold plate cooling, are more energy-efficient due to higher heat capacity of liquids and large latent heat. Boiling heat transfer, known as a phase change cooling method that leverages the latent heat of the working fluid for efficient heat transfer, demonstrates the superior efficiency compared to traditional air cooling and single-phase liquid cooling technologies. To meet the increasing demand of heat dissipation, numerous research efforts have been devoted to improving the boiling heat transfer performance including critical heat flux (CHF) and heat transfer coefficient (HTC). Surface modification has been used to enhance boiling heat transfer, such as employing microstructures, surface coating, tuning surface wettability, and so on. For this purpose, various surface structures including channels, fins, cavities, and porous structures have been developed through machining or sintering, which typically have simple shapes or uncontrollable random configurations, limiting the enhancement of the boiling heat transfer performance.

Embodiments described herein are 3D-printed metal triply periodic minimal surfaces (TPMS) that can achieve superior boiling heat transfer performance. Triply periodic minimal surfaces (TPMS) are a class of 3D structures characterized by a zero value of mean curvature at each point. They are periodic in three dimensions, and the surface energy is locally minimized. The large surface area to volume ratio, infinite interconnection, and smooth flow paths of TPMS structures may facilitate the transport of liquid and vapor through the structure, thereby leading to the enhanced boiling heat transfer performance.

In some embodiments, TPMS can deliver ultrahigh pool and flow boiling heat transfer performance. Using high-precision laser powder bed fusion (LPBF), we fabricated copper TPMS with rapid prototyping and fine control over unit-cell topology (primitive (P), gyroid (G), diamond (D)), cell size and phase, structure height, vertical cell size gradient factor, wall thickness, and/or surface roughness. For example, all three TPMS types may achieve CHF values above 450 W/cm² for pool boiling in water at atmospheric pressure. As an example, a vertically graded D-type TPMS with 2 mm height and a gradient factor of 1.5 attains a CHF of 728 W/cm², 32.4% higher than the maximum value previously reported. As an example in flow boiling, a D-type TPMS with 1.5 mm cell size and 2 mm height yields a CHF of 1089 W/cm² and an HTC of 32.4 W/cm²·K at a volumetric flow rate of 260 mL/min. As another example, at a unit cell size of 1.5 mm and a structure height of 0.5 mm, the P-type TPMS achieves a CoP of 648,562, more than twice the highest value reported in the literature. These 3D-printed metal TPMS surfaces with record-level boiling performance may be used for energy-efficient two-phase immersion and direct-to-chip cooling in data centers and electric vehicles.

Two-phase, boiling heat transfer is substantially different from single-phase heat transfer as in typical heat exchangers. As a result, the use of TPMS structures and the effectiveness of such structures for boiling heat transfer are unexpected. In heat exchangers, structured walls are used to separate two fluids with different temperatures. By contrast, pool and flow boiling may include a solid heating surface where a liquid is heated to generate bubbles. The design considerations of structures for pool and flow boiling versus heat exchangers are different. Heat exchangers involve heat transfer between two fluids through a wall, while pool and flow boiling described herein involves two-phase heat transfer between a TPMS structure and a working fluid. The TPMS design for pool boiling may focus on maximizing surface area contact with the working fluid and facilitate liquid supply into TPMS structures from the surroundings through a large capillary force. Without intending to be bound by theory, it is hypothesized that the liquid supply through the interconnected channels and/or high surface area may aid in sustaining high critical heat flux. At least partly because of these considerations, structures used for heat exchangers may not be readily applied to pool boiling uses. The ultrahigh CHF and high HTC from TPMS structured boiling surfaces are surprising.

Additionally, TPMS structures described for heat exchangers are typically single-phase convection cores, which are optimized to raise heat transfer by increased area and tortuosity while managing the accompanying pressure-drop penalty. Those design objectives do not translate to pool boiling or flow boiling, where performance involve different coupled mechanisms: nucleation behavior, bubble growth and departure, vapor venting, and maintenance of liquid contact with the heated surface to avoid dryout and the sharp performance collapse associated with critical heat flux (CHF) or dryout-type limits. In flow boiling, the geometry also may account for inherently unsteady two-phase behaviors (e.g., pressure-drop oscillations and associated temperature excursions) that do not arise in single-phase exchanger design and can dictate stability and CHF. As a result, a TPMS configuration that is attractive for exchanger convection (high area, strong disturbance) can be counterproductive for boiling if it promotes vapor blockage, suppresses rewetting pathways, or triggers two-phase instabilities, so using TPMS as a boiling surface may involve additional, non-overlapping design considerations beyond those for TPMS heat exchangers.

In some embodiments, the cooling structure is configured for flow boiling heat transfer, where the lattice is integrated into a flow channel to transfer heat to a flowing working fluid. In these embodiments, the TPMS lattice is disposed within and/or defines at least a portion of the flow channel so that a working fluid is forced to flow through, across, and/or around surfaces of the lattice while the lattice is thermally coupled to a heat source via a substrate. Heat conducted through the substrate is delivered to the TPMS lattice and removed by phase-change heat transfer, sensible heating, and forced convection associated with flow boiling on lattice surfaces. The working fluid may be any suitable coolant, including water, dielectric fluids, refrigerants, or mixtures thereof, and the flow may be single-phase upstream of the lattice and transition to two-phase within or downstream of the lattice depending on operating conditions. Flow through the channel may be driven by a pump, pressure differential, or other flow-inducing device, and the channel and lattice geometry may be selected to promote wetting, vapor removal, and liquid replenishment during flow boiling.

Embodiments described herein include at least three types of TPMS structured boiling surfaces (P, G, and D) fabricated through high-precision LPBF. Pool boiling and flow boiling experiments were conducted on all the fabricated TPMS structured boiling samples. The results have shown that TPMS structured boiling surfaces can achieve the superior boiling heat transfer performance. Embodiments can be tuned for different CHF, HTC, efficiency, and other characteristics by varying different parameters of the TPMS unit cells.

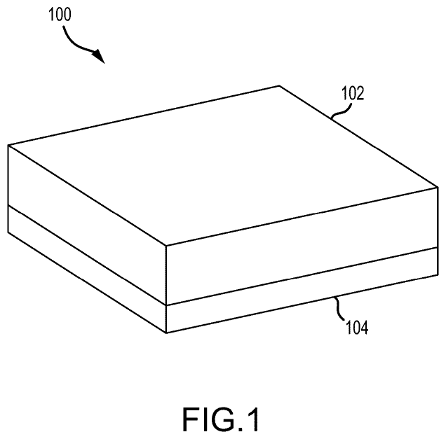

FIG. 1 shows a schematic diagram of a structure 100 for boiling heat transfer. Structure 100 includes TPMS heat transfer structure (lattice 102) printed on a substrate 104. Substrate 104 may be made of solid metal. For pool boiling, substrate 104 may be attached (e.g., by soldering) onto a heat source, while lattice 102 is immersed in a working fluid. The heat from the heat source is transferred to lattice 102 through the substrate. The heat from lattice 102 is then dissipated through the boiling heat transfer process on the surface. Heat from lattice 102 causes the working fluid to undergo a phase change from liquid to gas at nucleation sites on the surface of lattice 102.

For flow boiling, substrate 104 may be attached (e.g., by soldering) onto a heat source and lattice 102 may be disposed in, or form a portion of, a flow channel such that a working fluid is forced to flow across and/or through lattice 102. Heat conducted through substrate 104 may be removed by flow boiling on surfaces of lattice 102.

The heat transfer structure includes a lattice structure with TPMS unit cells. TPMS lattice structures exhibit distinctive geometric characteristics, which may be visualized through implicit surface modeling. This modeling technique enables the lattice structure to be precisely defined through a mathematical equation that is expressed as a sum comprising Fourier series terms. A method to simplify such an equation is a level-set approximation, which truncates the series to the leading term with a scalar field function Φ that satisfies Φ (x, y, z)=c.

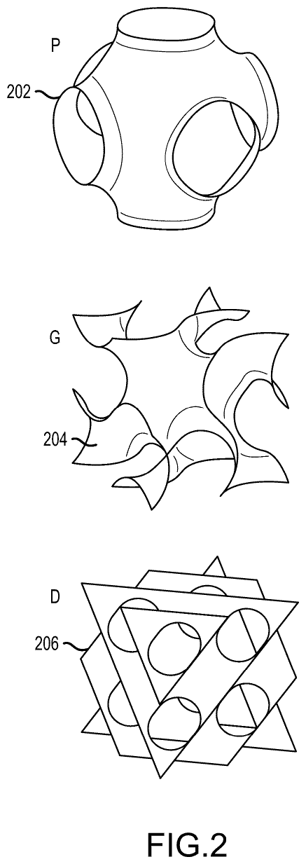

FIG. 2 shows example types of TPMS structures: P type 202, G type 204, and D type 206. Their corresponding surface equations are given in Table 1. In the surface equations shown in Table 1, ω=2π/l, where l represents the unit cell size. The TPMS unit cells can be arranged periodically along all three dimensions to meet the practical requirements.

TABLE 1
Example types of TPMS structures and
corresponding surface equations.

| TPMS | |
|---|---|
| type | Surface equation |
| P | Φ_{P} (x, y, z) = cos(ωx) + cos(ωy) + cos(ωz) = c |
| G | Φ_{G} (x, y, z) = cos(ωx)sin(ωy) + cos(ωy)sin(ωz) + |
| | cos(ωz)sin(ωx) = c |
| D | Φ_{D} (x, y, z) = sin(ωx)sin(ωy)sin(ωz) + cos(ωx)sin(ωy)sin(ωz) + |
| | sin(ωx)cos(ωy)sin(ωz) + sin(ωx)sin(ωy)cos(ωz) = c |

Other TPMS types may include neovius surface, lidinoid surface, I-WP (wrapped package surface), and Fischer-Koch S surface.

In some embodiments, hybridization between two TPMS types is controlled by a blending ratio that interpolates between corresponding implicit surface functions (e.g., between Φ_{G} and Φ_{P}) across space.

In some embodiments, one or more geometric parameters of the TPMS lattice may vary as a function of position. For example, a unit-cell-size gradient may be specified along a direction orthogonal to the substrate (a vertical gradient) and/or along a direction parallel to the substrate (a horizontal gradient). As used herein, a gradient factor may describe a magnitude of change in a parameter (e.g., unit-cell size) across a specified distance (e.g., across a lattice height or across a lateral span), for example as a ratio between an end value and a start value, or as a slope of a linear (or other) spatial profile.

The level-set approximation may be used to generate 3D isosurfaces using Cartesian coordinates and a level-set constant c. If the value of c is set to 0, the resulting minimal surfaces will split the space into subdomains of equal volumes. Based on the volumeless minimal surfaces, one can create TPMS sheet structure materials by thickening the minimal surfaces or solidifying the volume enclosed by two minimal surfaces of two different level-set constants. By spatially varying the surface equation and the level-set constant in Cartesian space, various functionally graded TPMS structures can be obtained.

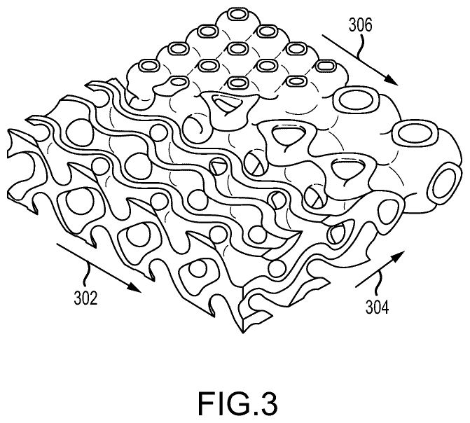

FIG. 3 shows a schematic diagram of the horizontal hybridization between G and P types of TPMS structures. FIG. 3 shows a smooth transition between different unit cell types (304), unit cell sizes (306), and wall thicknesses (302). A diversity of TPMS structures with tunable geometric parameters including unit cell size, unit cell type, wall thickness, porosity, tortuosity, surface roughness, and configuration gradient can be constructed. Additionally, the end surface of a TPMS structure may be changed through tuning the phase of the TPMS unit cell. The phase may be tuned by slicing the lattice (or ending manufacturing of the lattice) at different points in a direction orthogonal to the substrate (e.g., vertical in FIG. 3).

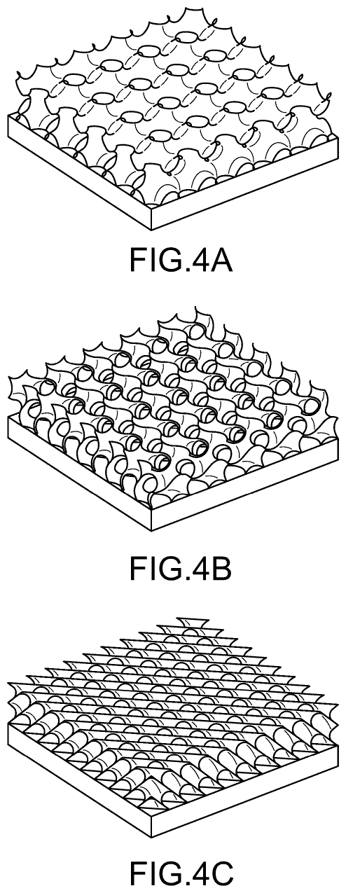

FIG. 4A, FIG. 4B, and FIG. 4C show example schematic diagrams of designed boiling heat transfer surfaces. FIG. 4A shows P type structures. FIG. 4B shows G type structures. FIG. 4C shows D type structures. In pool boiling embodiments, the TPMS structures are submerged in water during operation. In flow boiling embodiments, the TPMS lattice is disposed within and/or defines at least a portion of a flow channel filled with water.

The boiling heat transfer surfaces with 3D TPMS lattice structures may be formed through directly printing a periodic array of TPMS unit cells on a substrate. Both TPMS structures and the substrate may be made of metal. The metal may include copper, aluminum, stainless steel, or other metals, or their alloys to facilitate heat transfer. The TPMS structured boiling surfaces may be fabricated using high-precision LPBF. The TPMS structures may be printed through an integrated, end-to-end solution, encompassing design, modeling, fast slicing, and toolpath generation tailored for LPBF. As mentioned above, the TPMS structures may be designed and optimized using implicit mathematical functions, offering tunability of geometric parameters (the type, size, and phase of the TPMS unit cell, and wall thickness) to enhance the boiling heat transfer performance. Direct slicing and toolpath generation may be implemented via algorithms developed in MATLAB or other computational software, enabling seamless translation of implicit geometries into LPBF-ready instructions. During the manufacturing process, a high-power laser beam may selectively melt the powders according to the given instructions, building the designed TPMS structure layer by layer. Such geometric parameters may further include vertical and/or horizontal unit-cell-size gradient factors and unit-cell-type blending ratios.

### Example—Pool Boiling Experimental Setup

As examples, P, G, and D types TPMS structures of pure copper with different unit cell sizes were fabricated as boiling samples. Pure copper was selected because of its high thermal conductivity, which is beneficial for heat transfer applications. Each boiling sample has lateral dimensions of 1 cm×1 cm and a thickness of 1 mm.

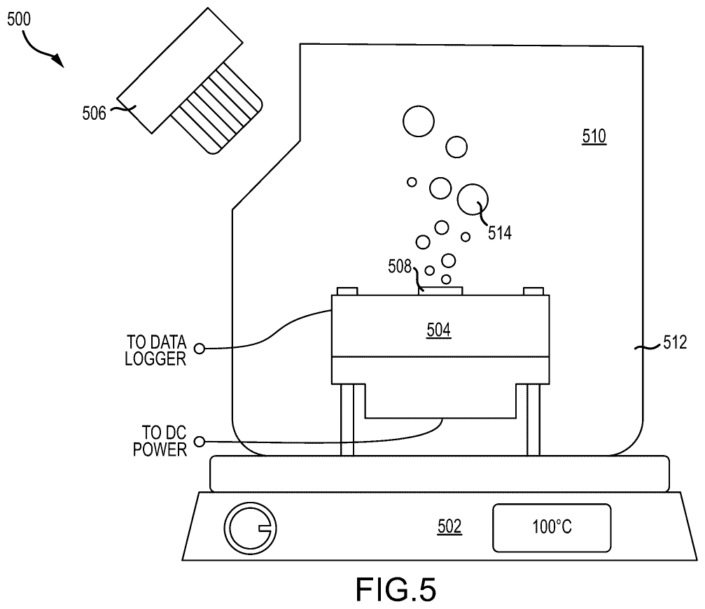

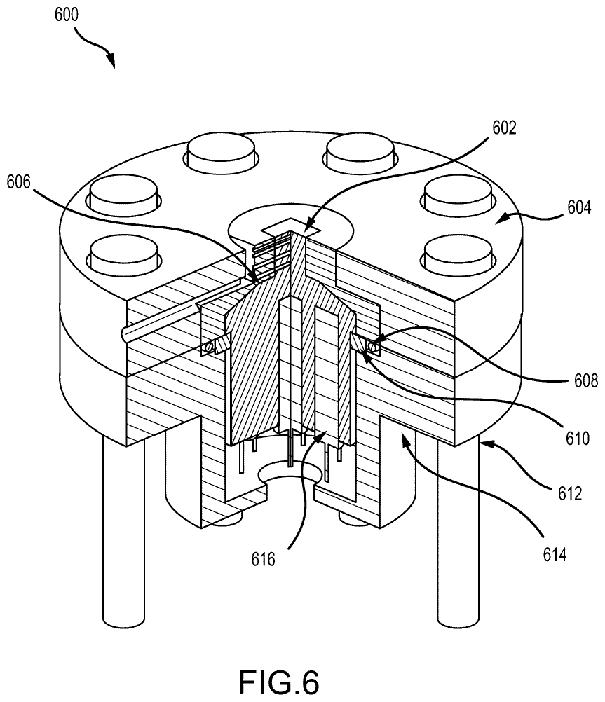

FIG. 5 shows the experimental setup 500 for characterizing the pool boiling heat transfer performance of TPMS structures. Experimental setup 500 includes a quartz chamber 510 filled with deionized water 512 on top of hot plate 502. Hot plate 502 heats deionized water 512 to near 100° C. TPMS structured surface 508 is bonded on a copper block of heating device 504, which is illustrated in greater detail in FIG. 6. Heating device 504 heats TPMS structured surface 508. Water vapor is generated by heating, creating bubbles, including bubble 514. High-speed camera 506 provides images of pool boiling phenomenon. Heating power of heating device 504 is gradually increased until reaching CHF.

FIG. 6 shows more detail of heating device 600 (e.g., heating device 504). Heating device 600 includes copper block 602, to which the TPMS structure is bonded. Copper block 602 allows conduction of heat from cartridge heater 616 to the TPMS structure. Polyimide thermocouple fastener 606 allows the installation of thermocouples along the centerline of the copper block to provide temperature readings. Other components, including upper teflon block 604, seal ring 608, ceramic ring 610, bolt 612, and bottom teflon block 614 act to encase the polyimide thermocouple fastener 606 and copper block 602 with the inserted cartridge heater 616 for thermal insulation.

### Example—Critical Heat Flux and Heat Transfer Coefficient

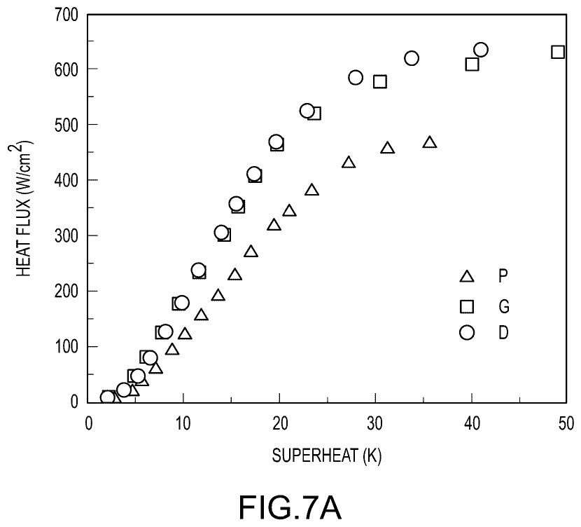

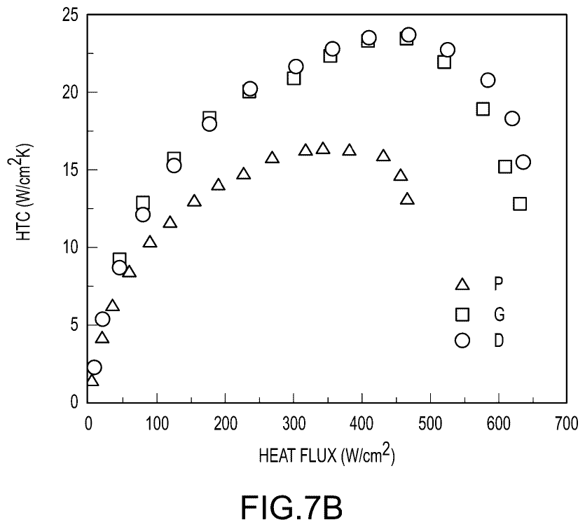

Pool boiling experiments were conducted on all three types of boiling samples using deionized water as the working fluid at atmospheric pressure. FIG. 7A shows the pool boiling curves for three types (P, G, and D) of 3D-printed pure copper TPMS boiling samples with the unit cell size of 1.5 mm. The structure height is 1 mm. The x-axis shows the wall superheat, e.g., the degrees (K) above the boiling point of water for the TPMS structured surface 508, which is estimated from the temperatures of the copper block 602 measured by thermocouples. For example, 30 refers to 30 K above the boiling point of water (373 K) for a total of 403 K. The y-axis shows the heat flux.

A critical heat flux (CHF) is the maximum heat flux that can be transferred from a heated surface to a surrounding fluid before transition to inefficient film boiling. A higher CHF is desired for boiling heat transfer. The critical heat flux is determined by the highest heat flux reached before the boiling surface temperature increases rapidly due to the occurrence of film boiling. For P type, the critical heat flux is 465 W/cm². For D type, the critical heat flux is 635 W/cm². For G type, the critical heat flux is 630 W/cm². G type and D type show similar heat fluxes.

FIG. 7B shows the calculated HTCs for three types (P, G, and D) of 3D-printed pure copper TPMS boiling samples with the unit cell size of 1.5 mm. The x-axis shows the heat flux in W/cm². The y-axis shows the heat transfer coefficient (HTC) in W/cm²·K. The HTC can be calculated from the heat flux divided by the wall superheat. The HTC in FIG. 7B may be the slope of the boiling curve in FIG. 7A.

G type and D type substantially overlap, reaching heat transfer coefficients above 20 W/cm²·K. Among the three TPMS structures, the D-type surface achieves the highest CHF of 635 W/cm² and the highest HTC of 23.7 W/cm²·K (unit cell size of 1.5 mm and structure height of 1.0 mm), demonstrating superior pool boiling heat transfer performance.

### Example—Unit Cell Size

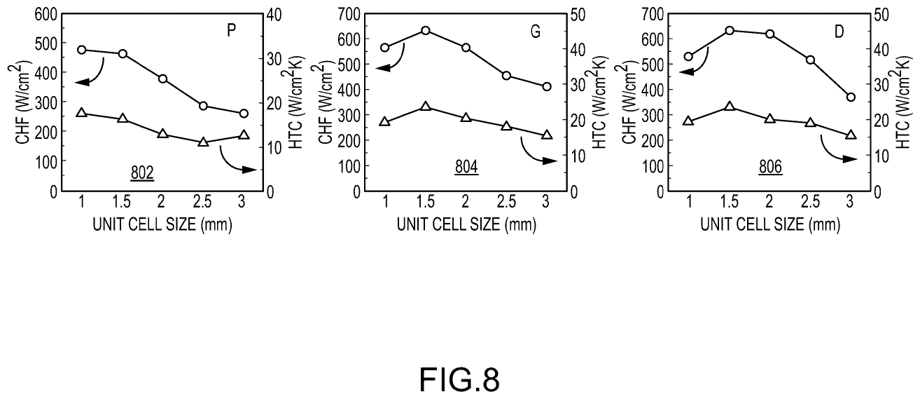

FIG. 8 shows how CHF and HTC vary according to unit cell size for P type 802, G type 804, and D type 806. The x-axis shows the unit cell size in millimeters. The left y-axis shows the critical heat flux in W/cm², with data points in circles. The right y-axis shows the heat transfer coefficient in W/cm²·K, with data points in triangles.

Samples with unit-cell sizes from 1.0 to 3.0 mm, in increments of 0.5 mm, were fabricated. For the G- and D-type TPMS surfaces, the CHF is maximized at a unit-cell size of 1.5 mm, likely due to the unit-cell dimension being comparable to the bubble departure diameter. In contrast, the P-type surface exhibits its highest CHF at a unit-cell size of 1.0 mm, which may be attributed to its relatively simple geometry and larger internal passages. Similarly, the G- and D-type surfaces achieve their highest HTCs at a unit-cell size of 1.5 mm, whereas the P-type sample reaches its maximum HTC at 1.0 mm.

### Example—Unit Cell Phase

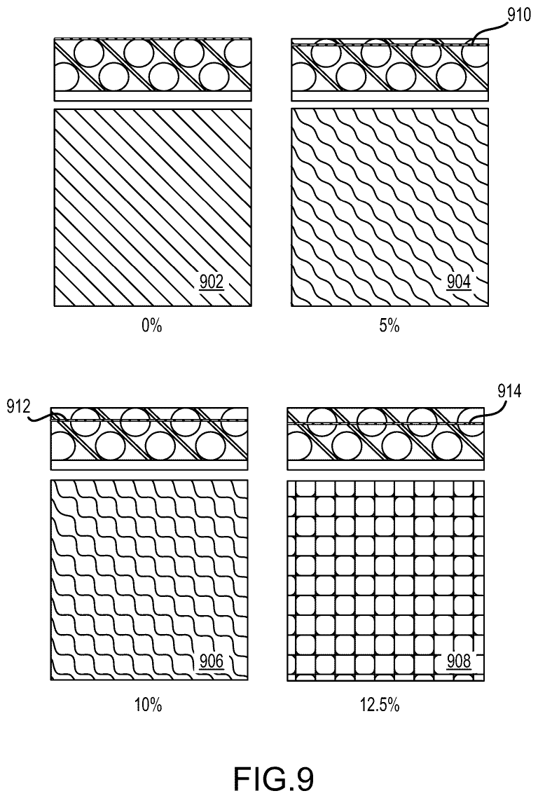

For the TPMS structured surfaces with the fixed unit cell size, the phase within a unit cell determines the outer surface of the sample. D-type TPMS structured surfaces were fabricated with a fixed unit cell size of 2 mm and a thickness of 1 mm but different unit cell phases. FIG. 9 shows schematic diagrams of different phases of unit cells in a cross-sectional view and a top view. Herein, the phase is defined as the percentage of a unit cell size. Diagram 902 shows a cross section of the structure for 0% phase and the resulting top surface having parallel diagonal lines. The top surface is the part of the TPMS structured surface that is at the maximum height of the structure. These diagonal lines are visible in D type of FIG. 4C. Diagram 904 shows a cross section of the structure for 5% phase, with dashed line 910 indicating the cut 5% of the unit cell size from the top. The top surface of the lattice shows wavy lines instead of the straight lines from diagram 902. Diagram 906 shows a cross section of the structure for 10% phase, with dashed line 912 indicating the cut at 10% of the unit cell size from the top. The top surface of the lattice shows even wavier lines than diagram 904. Diagram 908 shows a cross section of the structure for 12.5% phase, with dashed line 914 indicating a cut at 12.5% of the unit cell size from the top. The top surface of the lattice shows a grid-like pattern. The structures with different phases are tested for pool boiling critical heat flux and heat transfer coefficient. In some embodiments, the phase may include any translation or offset of the function along one or more axes. For example, a full unit cell may not be printed at the bottom of the substrate.

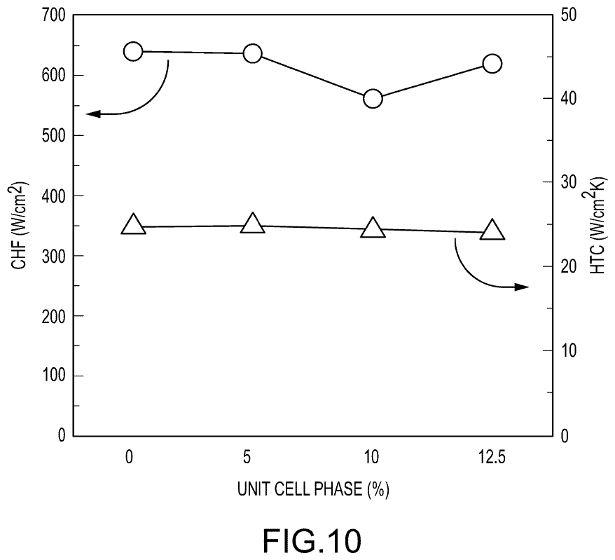

FIG. 10 shows the pool boiling CHF and HTC for different unit cell phases of FIG. 9. The x-axis shows the unit cell phase. The unit cell phase represents the proportion cut from the top of the lattice. The left y-axis shows the critical heat flux in W/cm², with data points in circles. The right y-axis shows the heat transfer coefficient in W/cm²·K, with data points in triangles.

Except the CHF for the sample with 10% unit cell phase, the CHFs and HTCs of the D-type samples with different unit cell phases are nearly the same, indicating that the unit cell phase of TPMS structures has no significant effect on the pool boiling heat transfer performance. The significantly lower CHF for the sample with 10% unit cell phase may be attributed to the lower structure height of this sample (0.9 mm) compared to other samples (~1.0 mm).

### Example—Structure Height

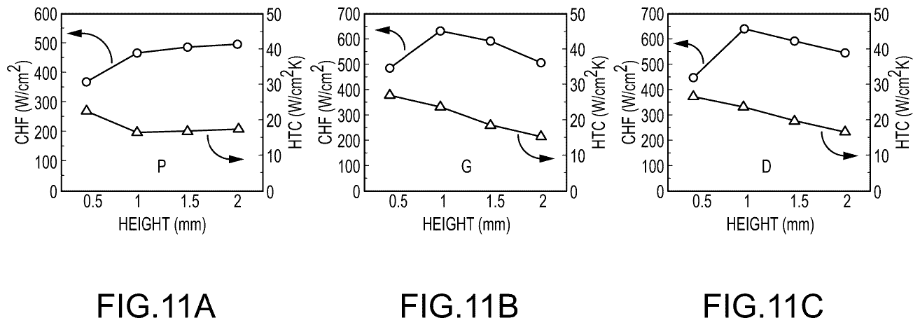

For TPMS structured surfaces with a fixed unit-cell size, the structure height determines the total heat-transfer area. P-, G-, and D-type TPMS surfaces with a unit-cell size of 1.5 mm and structure heights of 0.5, 1.0, 1.5, and 2.0 mm were fabricated to examine the effect of height on pool-boiling performance. As shown in FIGS. 11A-11C, the CHF of the P-type samples increases with structure height and reaches a maximum at 2.0 mm, whereas the CHFs of the G- and D-type samples peak at 1.0 mm. All three TPMS surfaces exhibit their highest HTC at a height of 0.5 mm, with HTC decreasing as the structure height increases beyond this value.

FIG. 11B and FIG. 11C reveal an unexpected trend for G- and D-type surfaces. While CHF increases as the structure height rises from 0.5 mm to 1.0 mm, CHF decreases at larger heights (1.5 mm and 2.0 mm). This suggests that, for complex 3D structures, boiling performance is governed not only by surface area but also by the efficient management of liquid supply and vapor removal. Excessive height lengthens the vapor escape path and leads to early dry-out.

### Example—Unit-Cell Size Gradient Factor

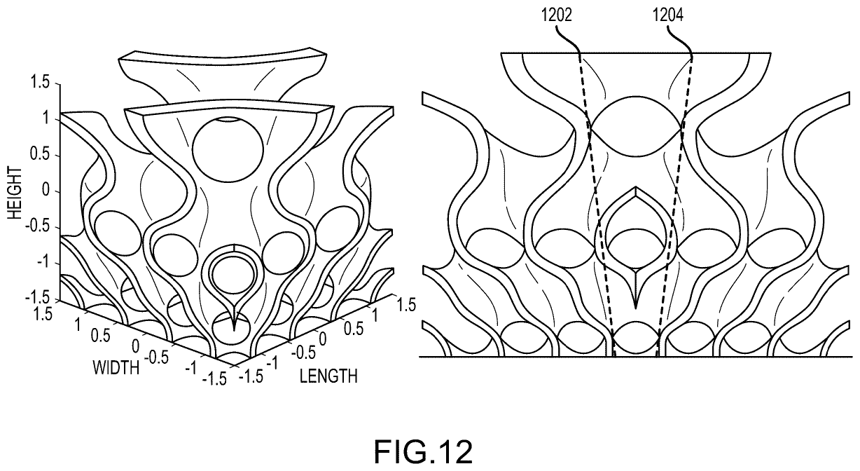

To mitigate this vapor-removal limitation, a vertically graded design strategy may be used. The bottom unit-cell size is fixed at 1.5 mm to maintain strong capillary liquid supply, while the unit-cell size is gradually increased along the vertical direction to form a more open vapor escape channel at the top, thereby delaying local dryout and enhancing CHF. FIG. 12 shows an example of a vertically graded design. Lines 1202 and 1204 are visual guides to show the increasing pore size in the unit cell going from bottom to top of the structure.

The vertical gradient factor is defined as shown in Equation 1.

$${G}_{vf} = ( {S}_{top} - {S}_{bottom} ) / H \qquad ( Equation 1 )$$

where G_{vf} is the vertical gradient factor, Sₜₒₚ is the unit-cell size at the top surface, S_{bottom} is the unit-cell size at the bottom surface, and His the structure height.

Similarly, horizontally graded TPMS structures can be designed by progressively increasing the unit-cell size along the flow direction, which is expected to reduce the pressure drop for flow boiling. The horizontal gradient factor is defined as:

$${G}_{hf} = ( {S}_{downstream} - {S}_{upstream} ) / L \qquad ( Equation 2 )$$

where G_{hf} is the horizontal gradient factor, Sᵤₚₛₜᵣₑₐₘ is the unit-cell size at the upstream side, S_{downstream} is the unit-cell size at the downstream side, and L is the flow-channel length. In pool boiling embodiments, upstream and downstream may refer to arbitrary ends of the substrate, while L is the lateral dimension of the sample.

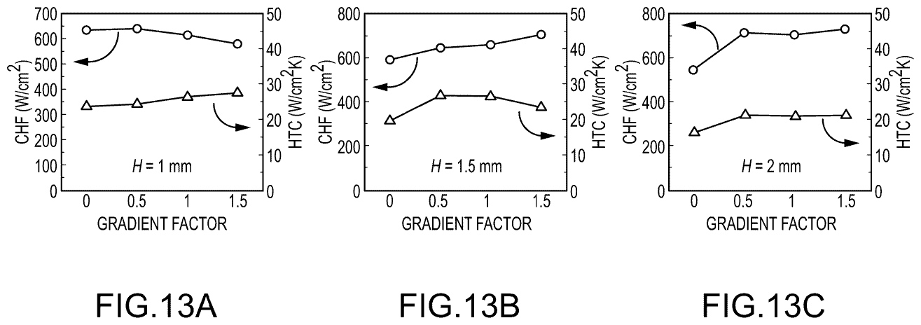

We systematically evaluated the effect of vertical gradient factors (0.5, 1.0, and 1.5) on the pool boiling performance of D-type TPMS structures at three heights (1.0, 1.5, and 2.0 mm) with the bottom unit cell size fixed at 1.5 mm. As shown in FIG. 13A, at a height of 1.0 mm, increasing the gradient factor leads to a slight decrease in CHF but an improvement in HTC. In contrast, at heights of 1.5 mm (FIG. 13B) and 2.0 mm (FIG. 13C), introducing a vertically graded design (G_{vf}>0) enhances CHF. Increasing the gradient factor effectively offsets the negative effect observed (FIG. 11B and FIG. 11C) for the uniform structure (G_{vf}=0), resulting in a pronounced increase in CHF with height. Consequently, a vertically graded D-type TPMS surface with a height of 2.0 mm and a gradient factor of 1.5 achieves a record-high CHF of 728 W/cm² (HTC of 21.3 W/cm²·K). These figures demonstrate that increasing the height of the structure while increasing the vertical gradient factor may maintain or increase CHF and/or HTC.

### Example—Blended Structure of D and G Types

As shown in FIGS. 7A-7B, the pool boiling performance of the D- and G-type TPMS structures are similar and have better performance than P-type TPMS structures. Blends of the two structures are investigated to identify improved configurations. The blended structure can be mathematically defined in Equation 3:

$${ϕ}_{b l e n d e r} ( x , y , z ) = α {ϕ}_{D} ( x , y , z ) + ( 1 - α ) {ϕ}_{G} ( x , y , z ) \qquad ( Equation 3 )$$

where Φ_{D}(x,y,z) and Φ_{G}(x,y,z) are the surface equations of the D- and G-type TPMS structures, respectively, and a is the blending ratio of the D-type TPMS structure.

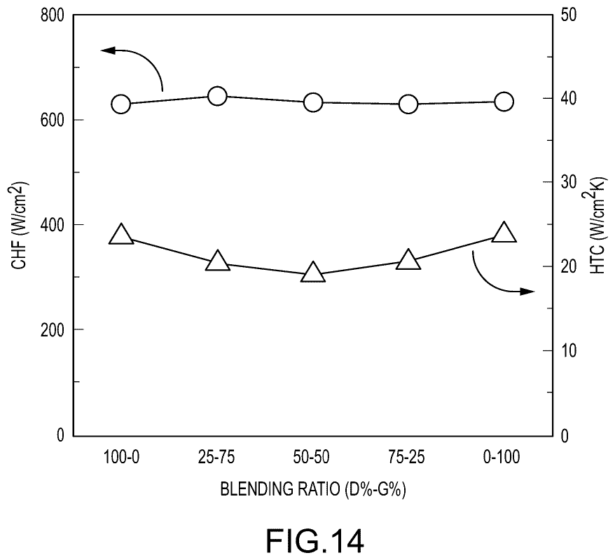

We systematically evaluated the pool boiling performance of blended structures with different D blending ratios (0, 0.25, 0.5, 0.75, 1) at a unit-cell size of 1.5 mm and a structure height of 1 mm. As shown in FIG. 14, the CHF at a blend ratio of 25% D and 75% G (647 W/cm²) is slightly higher than the value for pure D type structure (635 W/cm²). The HTCs of the blended structures with the D blending ratios of 0.25, 0.5, and 0.75 are lower than the values for either pure D type or G type structures. In summary, the D-G blended structures show a slightly enhanced CHF but reduced HTC for pool boiling.

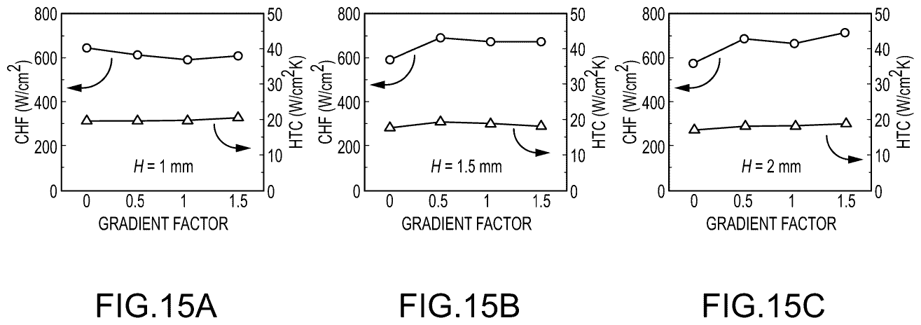

As shown in FIGS. 15A-15C, different structure heights and different vertical gradient factors were tested for a blended structure of 25% D and 75% G. The different structure heights tested were 1.0 mm (FIG. 15A), 1.5 mm (FIG. 15B), and 2.0 mm (FIG. 15C). The different vertical gradient factors tested were 0.5, 1.0, and 1.5, shown on the x-axes of each graph. The variation of the pool boiling CHF with the vertical gradient factor for the blended structure is similar to the pure D-type TPMS structures (FIGS. 13A-13C), which confirms that the vertically graded design can effectively enhance the CHF at larger structure heights. Consequently, the blended structure with a height of 2 mm and a vertical gradient factor of 1.5 achieves a maximum CHF of 717 W/cm², which is close to the value for pure D type structure (728 W/cm²). The HTCs are almost unchanged when increasing the vertical gradient factor.

Results show that vertically graded blended structure can enhance the CHF without sacrificing HTC in contrast to the vertically graded D type structure. The vertical gradient design may effectively enhance the CHF of both D type and blended structure, which may be applicable to other structures as well.

### Example—Comparison

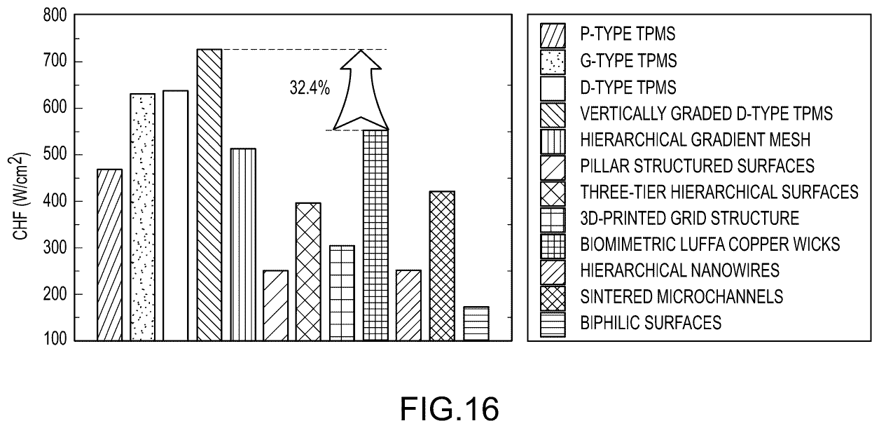

FIG. 16 shows a comparison of the critical heat fluxes of the pure copper TPMS structured surfaces tested with pool boiling heat transfer structures reported in literature. The x-axis shows the different structures (from left to right): P-type TPMS, G-type TPMS, D-type TPMS, vertically graded D-type TPMS, hierarchical gradient mesh (S. Zhang et al., Appl. Therm. Eng. 219 (2023) 119513), pillar structured surfaces (Q. Li et al., Appl. Therm. Eng. 215 (2022) 118924), three-tier hierarchical surfaces (J. Li et al., ACS Nano 13 (2019) 14080-14093), 3D-printed grid structure (C. Zhang et al., Int. J. Heat Mass Transf. 128 (2019) 570-580), biomimetic luffa copper wicks (M. Xu et al., Appl. Therm. Eng. 267 (2025) 125787), hierarchical nanowires (R. Wen et al., Nano Energy 38 (2017) 59-65), sintered microchannels (A. Jaikumar et al., Int. J. Heat Mass Transf. 95 (2016) 795-805), and biphilic surfaces (A.R. Betz et al., Int. J. Heat Mass Transf. 57 (2013) 733-741).

As shown in FIG. 16, all four TPMS structures (P, G, D, and vertically graded D) can achieve the superior CHFs above 450 W/cm² for pool boiling in water at atmospheric pressure. Particularly, the vertically graded D-type TPMS structured surface with 2 mm height and a gradient factor of 1.5 demonstrates the highest CHF of 728 W/cm², which is 32.4% higher than the maximum value (550 W/cm²) reported in the literature. Hence, the TPMS structures show unexpectedly improved results over alternative structures for pool boiling.

The pool boiling heat transfer performance of TPMS structured boiling surfaces may be further enhanced through parametric optimization and/or functionally graded TPMS structures. Parametric optimization may include varying lattice structure, surface roughness, wall thickness of TPMS structures, and/or other suitable parameters. Functionally graded TPMS structures may be developed to facilitate liquid supply into the TPMS structure and further improve the CHF and HTC.

### Example—Server Cooling

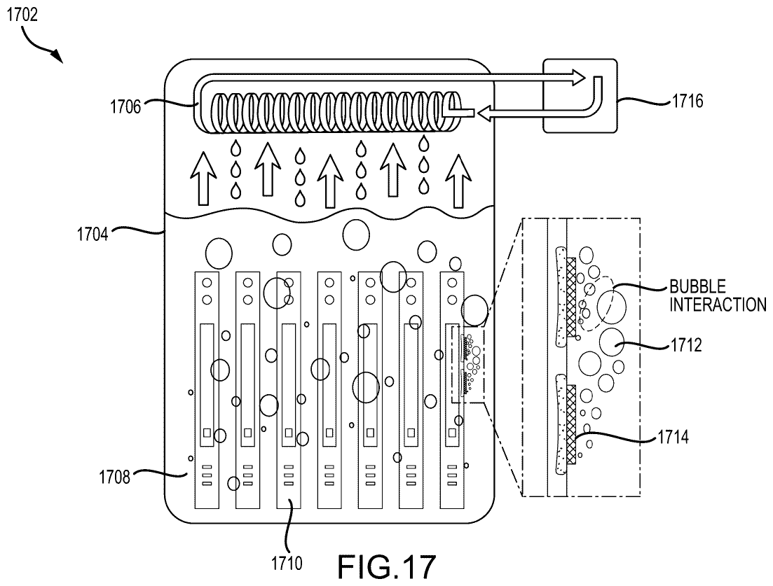

FIG. 17 shows a configuration 1702 for cooling servers. Configuration 1702 involves a vessel 1704. Vessel 1704 includes a plurality of server blades (e.g., server blade 1710) submerged in working fluid 1708, which may include water, coolants, or refrigerants. TPMS structures 1714 are mounted to processors on the server blade 1710. The inset may show a large-area chip or multiple chips. The heat from the processors flows through TPMS structures 1714 and causes working fluid to change phase from a liquid to a gas. Bubbles (e.g., bubble 1712) are formed and flow upward, carrying heat to a condenser 1706. Water vapor condenses against condenser 1706 and returns as a liquid surround the server blades. The condenser may involve water cooling 1716. FIG. 17 shows multiple TPMS structures 1714. In some embodiments, a continuous TPMS structure covering one or more processors may be used instead of a plurality of TPMS structures.

### Example—Flow Boiling Experimental Setup

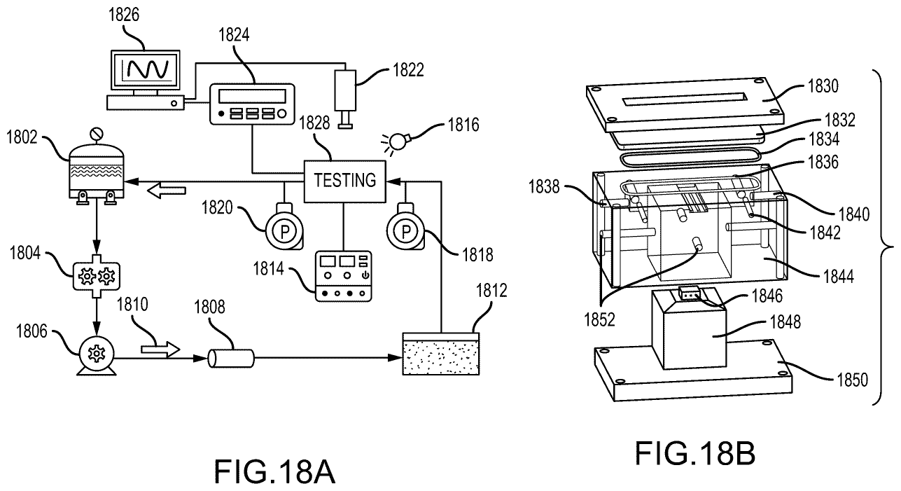

Flow boiling experiments were also performed on all three types of TPMS structures with deionized water at atmospheric pressure. FIG. 18A presents a schematic of the flow boiling experimental setup. Degassed deionized water is stored in a water tank 1802 and used as the working fluid. A digital gear pump 1806 circulates the water through the flow loop in flow direction 1810, and the flow rate is monitored by a flow meter 1804. A microfilter 1808 downstream of the digital gear pump 1806 removes impurities from the water. The water then passes through a thermostatic bath 1812, where its temperature can be controlled, before entering the testing section 1828, where TPMS unit cells are tested. Testing section 1828 is described in greater detail with FIG. 18B.

Inlet and outlet pressures are measured by pressure transducers 1818 and 1820 connected to the inlet and outlet ports of testing section 1828. Thermocouples in testing section 1828 are connected to a data logger 1824 (Agilent 34970A) for temperature acquisition. A DC power supply 1814 (Faith FTP020) provides power to the cartridge heaters. A high-speed camera 506 (FASTCAM Mini UX, Photron) equipped with a microscope is used to capture bubble dynamics. A light source 1816 assists with improving image quality captured by the camera. A computer 1826 is in communication with both data logger 1824 and high-speed camera 1822 in order to control image and data acquisition. Computer 1826 can store image data, temperature data, pressure data, and other data.

The detailed structure of the testing section 1828 is shown in FIG. 18B. Testing section 1828 includes a copper block 602 embedded in a base block 1844 (e.g., a polyether ether ketone [PEEK] block). The copper block 1848 heats the sample during boiling and enables determination of boiling curves. Nine cartridge heaters are inserted into the lower portion of the copper block 1848 to supply heating power. The upper portion of the copper block 1848 has a 10 mm×10 mm square cross section, matching the size of the boiling samples. Before experiment, the sample is soldered onto the top surface of the copper block 1848. Three thermocouples are embedded in holes for installing thermocouples 1846 along the flow-direction centerline in a plane 1.5 mm below the top surface to record the temperature distribution. Two additional thermocouples are installed in holes for installing thermocouples 1842 at the fluid inlet 1838 and fluid outlet 1840 to monitor the water temperatures. For all tests, the inlet water subcooling is maintained at 10° C.

Copper block 1848 may be mounted to supporting block 1850. The top of base block 1844 is sealed with seal ring 608, quartz glass 1832, and cover plate 1830 to prevent water from escaping other than through the fluid outlet 1840.

Two volumetric flow rates, 140 mL/min and 260 mL/min, were tested. Unlike the pool boiling experimental setup, the flow boiling system uses a pump for circulation, leading to additional power consumption. To assess the overall system efficiency, the coefficient of performance (CoP) is defined in Equation 4:

$$C o P = \frac{Q}{{P}_{p u m p}} = \frac{Q}{V Δ P} \qquad ( Equation 4 )$$

where Q is the heat transfer rate and Pₚᵤₘₚ is the required pumping power, determined by the pressure drop ΔP and the volumetric flow rate V. The CoP for flow boiling represents the heat removed per unit pumping power. Therefore, a larger CoP indicates better overall thermal-hydraulic performance of the flow boiling system.

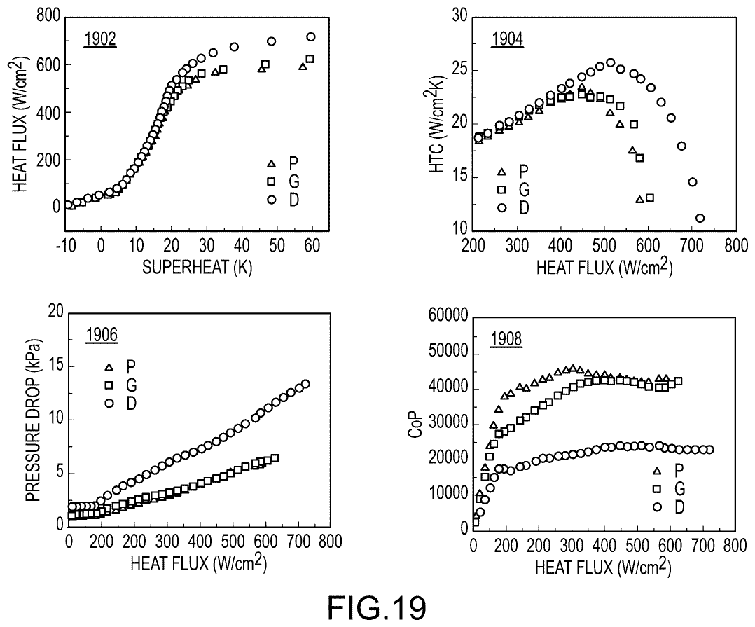

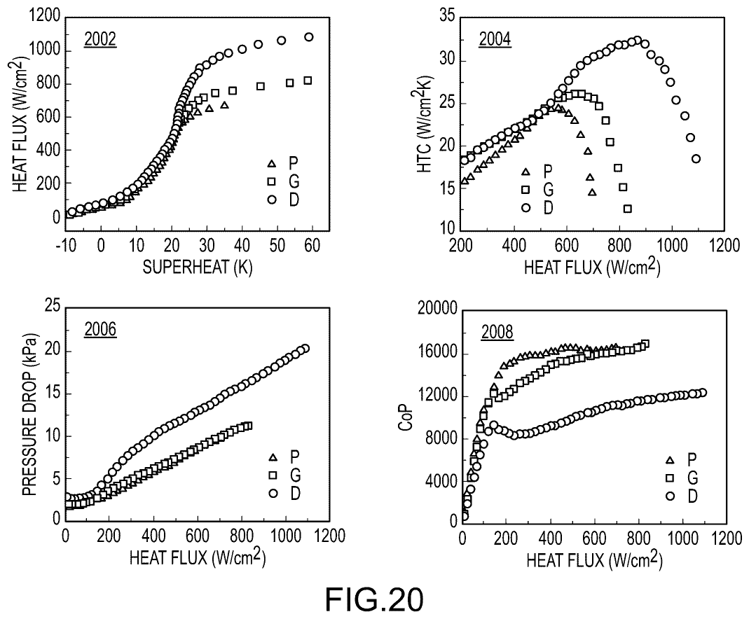

FIG. 19 and FIG. 20 show the flow boiling heat transfer performance for three types of 3D-printed pure copper TPMS boiling samples (P, G, and D) with a unit cell size of 1.5 mm and a structure height of 2 mm, at volumetric flow rates of 140 mL/min and 260 mL/min, respectively. Graphs 1902 and 2002 are flow boiling curves. Graphs 1904 and 2004 show HTCs. Graphs 1906 and 2006 show pressure drops. Graphs 1908 and 2008 show CoPs.

Increasing the flow rate enhances the flow boiling heat transfer performance. Among the three TPMS structures, the D-type surface achieves the maximum heat flux of 1089 W/cm² (graph 2002) and the highest HTC of 32.4 W/cm²·K (graph 2004) at a volumetric flow rate of 260 mL/min, demonstrating superior flow boiling heat transfer performance. For all three samples, the pressure drop increases with heat flux, and the D-type surface exhibits a higher pressure drop than the other two samples. At both volumetric flow rates, the CoP for all three samples rises sharply once boiling initiates and then remains relatively high up to the maximum heat flux. Among the three TPMS structures, the P-type surface achieves the highest CoP, while the D-type surface exhibits the lowest value. Therefore, the D type surface may suitable for high power applications as it can achieve ultrahigh heat flux and higher HTC, while the P and G types surfaces may be beneficial for medium or low power applications as they require lower pumping power.

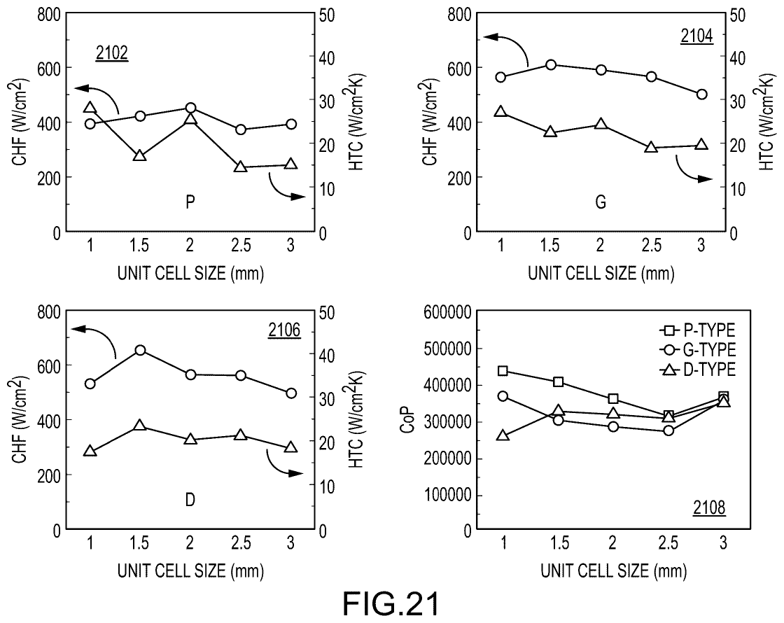

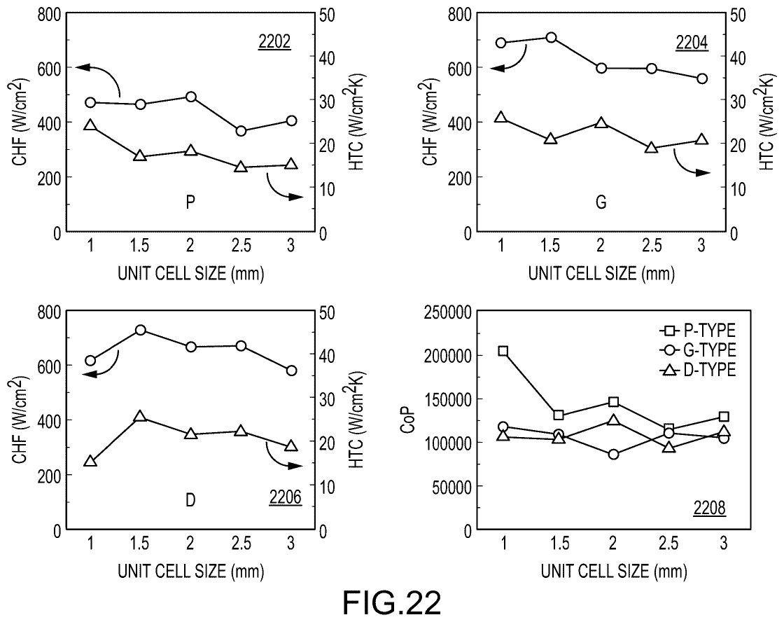

FIG. 21 and FIG. 22 show influence of unit cell size on flow boiling heat transfer performance, including CHF, HTC, and CoP, for all three types of TPMS boiling surfaces at a fixed structure height of 1 mm. FIG. 21 shows results at a volumetric flow rate of 140 mL/min. FIG. 22 shows results at a volumetric flow rate of 260 mL/min. Graphs 2102 and 2202 are for P-type structures. Graphs 2104 and 2204 are for G-type structures. Graphs 2106 and 2206 are for D-type structures. Graphs 2108 and 2208 show the CoP for all structures.

The CHF is maximized at a unit cell size of 1.5 mm for the G-type and D-type TPMS structured surfaces, consistent with the pool boiling results. The P-type surface achieves its maximum CHF at a unit cell size of 2.0 mm. The P-type and G-type TPMS structured surfaces provide the highest HTC at a unit cell size of 1.0 mm, while the D-type surface reaches its maximum HTC at 1.5 mm. With increasing volumetric flow rate, the CoP exhibits a decreasing trend. The P-type TPMS structured surface shows a relatively higher CoP, with a maximum value of 441,332 at a volumetric flow rate of 140 mL/min. Overall, the effect of unit cell size on CoP is limited. Among three TPMS structures, the D-type surface with the unit cell size of 1.5 mm achieves the highest CHF at a volumetric flow rate of 260 mL/min (726 W/cm²). Therefore in additional experiments, the unit cell size is fixed at 1.5 mm for optimizing other parameters.

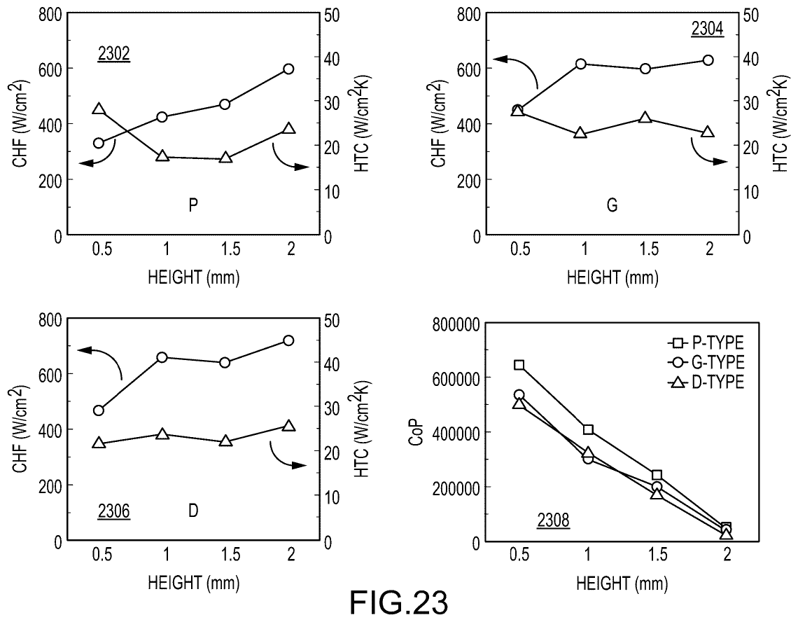

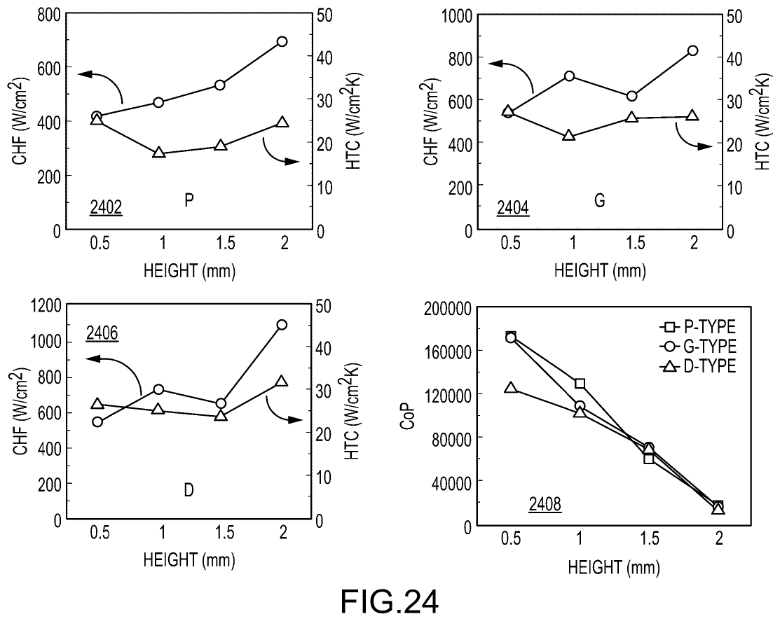

FIG. 23 and FIG. 24 show the results of investigating the flow boiling heat transfer performance of P-, G-, and D-type TPMS structured surfaces with a fixed unit cell size of 1.5 mm at structure heights of 0.5, 1.0, 1.5, and 2.0 mm. The channel height is fixed at 2.0 mm. FIG. 23 shows results at a volumetric flow rate of 140 mL/min. FIG. 24 shows results at a volumetric flow rate of 260 mL/min. Graphs 2302 and 2402 are for P-type structures. Graphs 2304 and 2404 are for G-type structures. Graphs 2306 and 2406 are for D-type structures. Graphs 2308 and 2408 show the CoP for all structures.

The CHF of the P-type samples increases with structure height and reaches its maximum at 2.0 mm. For the G- and D-type samples, the CHF first increases, then decreases, and subsequently increases again as the structure height increases. Without intending to be bound by theory, the initial increase in maximum heat flux with the increase of the structure height from 0.5 mm to 1.0 mm is primarily attributed to the enlarged heat transfer area. However, at a larger structure height of 1.5 mm, bubble removal by vertical buoyancy may become increasingly difficult, which impairs heat transfer, as indicated by pool boiling results at structure heights larger than 1.0 mm (FIGS. 11B-11C).

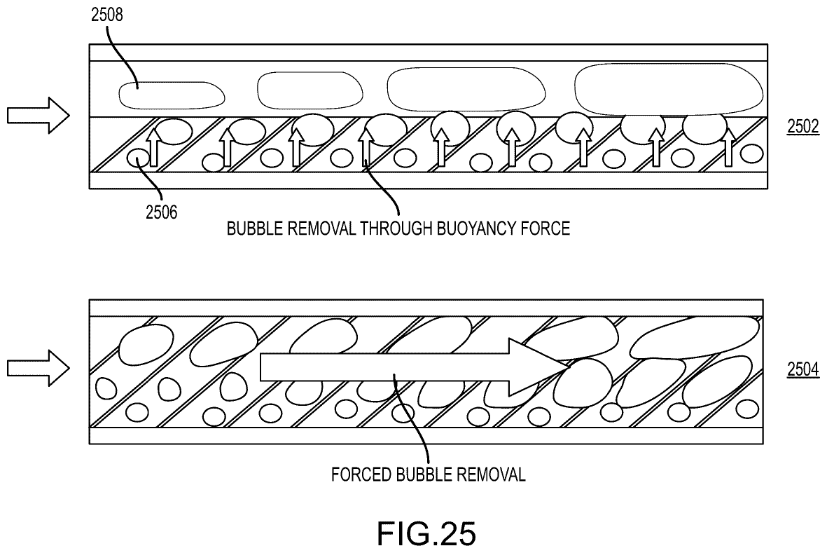

FIG. 25 shows configuration 2502, where the TPMS structure has a height of 1.0 mm and the channel has a height of 2.0 mm. Bubbles (e.g., bubble 2506) formed within the TPMS structures are driven upward by a buoyancy force to be in section of the channel without any TPMS structure. The bubbles (e.g., bubble 2508) are then convectively flowed away by the flow of the water above the TPMS structure.

Configuration 2504 shows the TPMS structure at a height of 2.0 mm with the channel height being 2.0 mm. At this TPMS structure height, the gap between the TPMS top surface and the upper cover plate disappears, forcing all cooling fluid to flow through the internal TPMS channels and resulting in strong forced bubble removal.

At a structure height of 0.5 mm, the CoP of the P-type TPMS surface reaches 648,562 (graph 2308), more than twice the highest value reported in the literature, which is primarily attributed to the relatively high CHF and significantly lower pressure drop at low structure-to-height ratio. As the height increases, the CoP of all samples decreases significantly, and the differences among the three TPMS types simultaneously diminish.

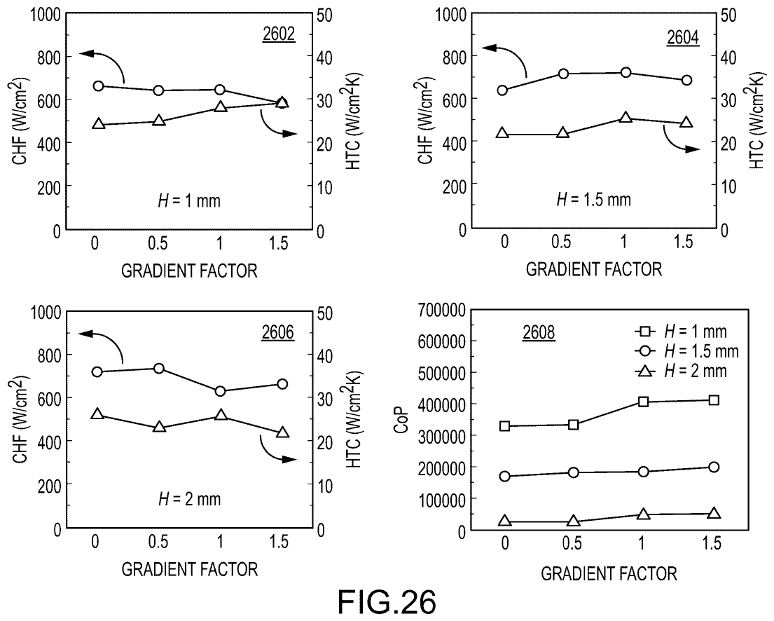

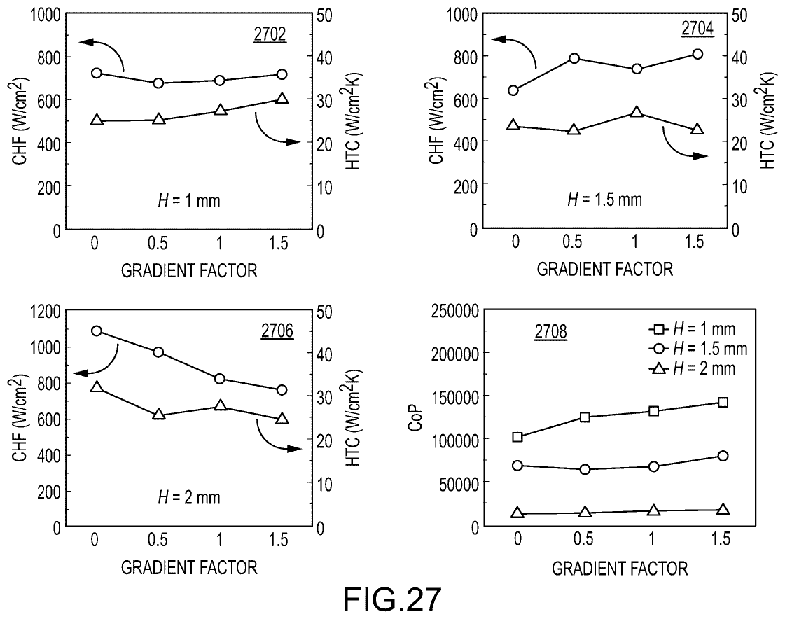

FIG. 26 and FIG. 27 show results from investigating flow boiling heat transfer performance of vertically graded D-type TPMS configurations with gradient factors of 0.5, 1.0, and 1.5 at structure heights of 1.0, 1.5, and 2.0 mm. The bottom unit cell size is fixed at 1.5 mm. FIG. 26 shows results at a volumetric flow rate of 140 mL/min. FIG. 27 shows results at a volumetric flow rate of 260 mL/min. Graphs 2702 and 2802 are for a height of 1.0 mm. Graphs 2704 and 2804 are for a height of 1.5 mm. Graphs 2706 and 2806 are for a height of 2.0 mm. Graphs 2708 and 2808 show the CoP for all structures.

At a volumetric flow rate of 140 mL/min (FIG. 26), the influence of the vertical gradient factor on flow boiling heat transfer performance is not significant. HTC enhancement is observed at heights of 1.0 mm (graph 2602) and 1.5 mm (graph 2604). At a higher volumetric flow rate of 260 mL/min (FIG. 27), increasing the vertical gradient factor at a height of 1.0 mm (graph 2702) enhances the HTC, likely as a result of improved bubble removal. At a height of 1.5 mm (graph 2704), introducing a gradient design (gradient factor>0) increases the CHF, whereas at a height of 2.0 mm (graph 2706), the gradient design reduces CHF, as bubble removal is not improved when the structure height is the same as the channel height and the heat transfer area is reduced with the increase of the vertical gradient factor. Since the graded configuration increases the equivalent flow cross-sectional area and thereby reduces the pressure drop, the CoP tends to increase with increasing gradient factor (graphs 2608 and 2708).

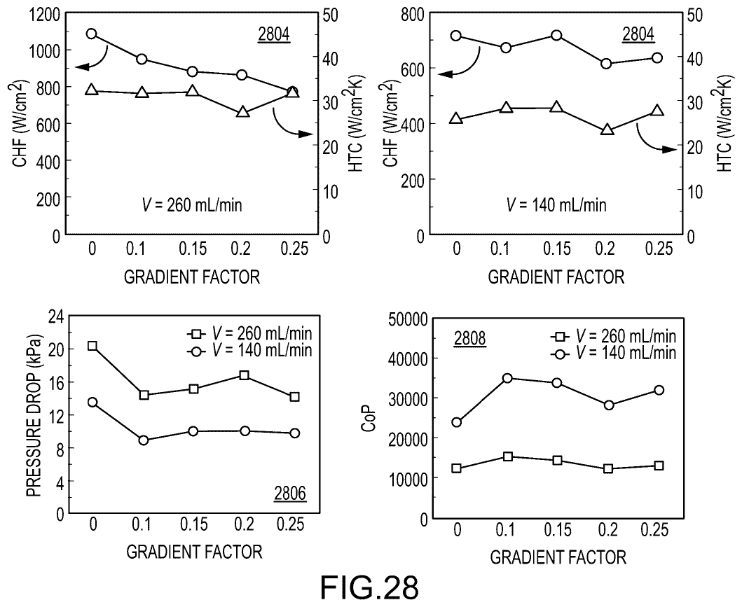

FIG. 28 shows the effects of varying the horizontal gradient factor on flow boiling heat transfer performance of D-type TPMS structures with a structure height of 2.0 mm. Graph 2802 is for a volumetric flow rate of 260 mL/min. Graph 2804 is for a volumetric flow rate of 140 mL/min. Graph 2806 shows the pressure drop. Graph 2808 shows the CoP.

The unit cell size at the upstream side is fixed at 1.5 mm and gradually increases along the flow direction toward the downstream side. As shown in graphs 2802 and 2804, the CHF generally decreases with increasing horizontal gradient factor, presumably due to the reduced heat transfer area. Also shown in graphs 2802 and 2804, the influence of the horizontal gradient factor on HTC is relatively limited. In graph 2806, the pressure drop first decreases with the horizontal gradient factor and then roughly flattens at both flow rates. As a result, a maximum CoP is observed at a horizontal gradient factor of 0.1, as shown in graph 2808.

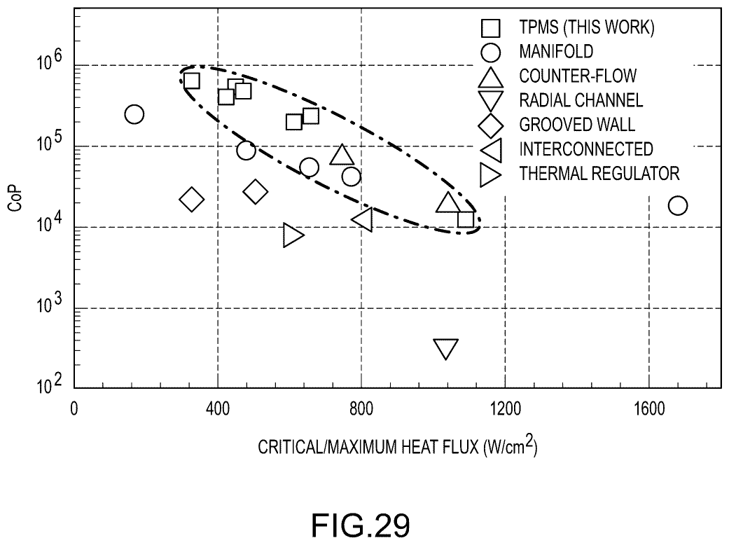

FIG. 29 is a comparison of the flow boiling performance of all three TPMS types with the results in the literature. CoP is on the y-axis, and CHF is on the x-axis. The structure characteristics of TPMS surfaces enable them to achieve a high CoP in flow boiling, which is of great significance for engineering applications. At a structure height of 0.5 mm, the CoP of the P-type TPMS surface reaches 648,562, more than twice the highest value reported in the existing literature. At a structure height of 2 mm, the D-type TPMS surface achieves a flow boiling CHF of 1089 W/cm², which is high compared with values reported in the literature.

As shown in FIG. 29, TPMS structures can be tuned to achieve both high CoP and high CHF. Particularly, the D-type surface is beneficial for high power applications due to high CHF and moderate CoP, while the P-type or G-type surface can be used for medium or low power applications due to high CoP. At a fixed CHF, the CoP of TPMS structures is much higher than (CHF range: 300-700 W/cm²) or comparable to (CHF~1000 W/cm²) other structures in the literature, demonstrating the advantages of TPMS structures for flow boiling heat transfer.

### Example Cooling Structures

Example systems may include a cooling structure for boiling heat transfer, which may include pool boiling or flow boiling heat transfer. The cooling structure may include a substrate. The substrate may be planar. The substrate may be configured to be impervious to a liquid. For example, the substrate may be a non-porous solid. The substrate may be a fixed heat source or may be configured to be in thermal communication with a fixed heat source. Thermal communication may refer to a relationship between components that permits heat to flow between them by conduction, convection, and/or radiation, either directly or through one or more intermediate structures or materials. The primary thermal communication path may be by conduction. The substrate may be soldered, attached through thermal interface materials, or otherwise bonded to the fixed heat source. The fixed heat source may be a processor. In some embodiments, the fixed heat source may be a housing containing a processor. In some embodiments, the fixed heat source may be electric vehicle power electronics. The fixed heat source may be a solid. The fixed heat source may exclude a component of a heat exchanger, including a shell or a tube. The substrate may include a conductive metal, including copper, silver, aluminum, any suitable metal, or alloys thereof. The substrate may have a thickness less than a unit cell size of a TPMS unit cell.

The substrate thickness may be less than the substrate length and/or substrate width. The substrate may have a thickness in a range from 0.1 to 0.2 mm, 0.2 to 0.3 mm, 0.3 to 0.4 mm, or 0.4 to 0.5 mm. The substrate may include any substrate described herein, including substrate 104 or those described with FIG. 4A, FIG. 4B, FIG. 4C, or FIG. 9. The cooling structure may include any cooling structure described herein, including structure 100 or those of FIG. 4A, FIG. 4B, FIG. 4C, or FIG. 9.

The cooling structure may include a lattice disposed on the substrate. The lattice may include a plurality of triply periodic minimal surface (TPMS) unit cells. The TPMS unit cells include surfaces that are periodic in a first direction, a second direction, and a third direction. The three directions may be x, y, and z directions in a Cartesian coordinate system. The lattice may include any lattice described herein, including lattice 102.

The lattice may be directly printed on a surface of the substrate. The surface may be characterized by a substrate length in the first direction and a substrate width in the second direction. The lattice may be characterized by a lattice height in the third direction. The lattice height may be less than the substrate length and/or may be less than the substrate width. The substrate may include a processor or other heat source. The lattice may be directly printed on electronic chips by electrochemical additive manufacturing for cooling.

The lattice may be characterized by a height orthogonal to a surface of the substrate. A TPMS unit cell of the plurality of TPMS unit cells may be characterized by a unit cell size. The height may be less than, equal to, or greater than the unit cell size. The height may be in a range from 0.5 to 1.0 mm, 1.0 to 1.5 mm, 1.5 to 2.0 mm, 2.0 to 3.0 mm, 3.0 to 4.0 mm, 4.0 to 5.0 mm, or greater than 5.0 mm.

A TPMS unit cell of the plurality of TPMS unit cells may be characterized by a unit cell size. A ratio of the height to the unit cell size may be in a range from 0.25 to 0.50, 0.50 to 0.75, 0.75 to 0.80, 0.80 to 0.90, 0.90 to 1.0, 1.0 to 1.1, 1.1 to 1.2, 1.2 to 1.25, 1.25 to 1.50, 1.50 to 2.0, 2.0 to 3.0, 3.0 to 4.0, 4.0 to 5.0, 5.0 to 6.0 or greater than 6.0. The unit cell size may be in a range from 0.75 to 1.0 mm, 1.0 to 1.5 mm, 1.5 to 2.0 mm, 2.0 to 2.5 mm, 2.5 to 3.0 mm, 3.0 to 4.0 mm, 4.0 mm to 5.0 mm, or greater than 5.0 mm.

The plurality of TPMS unit cells may include P-type TPMS unit cells (e.g., unit cells with P-type surfaces), G-type TPMS unit cells, D-type TPMS unit cells, neovius unit cells, lidinoid unit cells, I-WP (wrapped package surface) unit cells, Fischer-Koch S unit cells, or any combination thereof. In some embodiments, the TPMS unit cells may be a blend of different surfaces (e.g., as described with FIG. 14). In some embodiments, the TPMS unit cells may include unit cells that are distinctly one surface and then other unit cells that are another surface. The TPMS unit cell may be any unit cell described herein, including those described with FIG. 2 or FIG. 3. The TPMS unit cells may be described by surface equations in Table 1. The TPMS unit cells may be described by any surface equations associated with the different types of unit cells. The TPMS unit cells may be described by surface equations that are functions involving sinusoidal functions of variables for the three directions.

In some embodiments, the lattice is tunable by adjusting one or more geometric parameters, including porosity and tortuosity. Porosity may refer to a void fraction of the lattice volume, and tortuosity may refer to a degree to which liquid and/or vapor flow paths through the lattice deviate from a straight path (e.g., an effective path-length ratio). The porosity and/or tortuosity may be selected to control liquid replenishment, vapor escape, bubble departure, and/or pressure drop for a target boiling performance. In some embodiments, tunability further includes adjusting an integer number of unit cells in each of the first, second, and third directions, thereby setting overall lattice length, width, and height. In some embodiments, one or more unit-cell parameters (e.g., unit-cell size, wall thickness, unit-cell type, phase, porosity, and/or tortuosity) may be held constant or may vary independently along any of the first, second, and third directions, including along a flow direction and/or orthogonal to the substrate.

The lattice may be formed by additive manufacturing (e.g., 3D printing). The lattice may include a metal. The metal may include copper, aluminum, nickel, titanium, alloys thereof, stainless steel, cobalt-chrome, or any suitable metal. The plurality of TPMS unit cells may include identical TPMS unit cells. The plurality of TPMS unit cells may include TPMS unit cells of different TPMS types. The plurality of TPMS unit cells may include TPMS unit cells characterized by different unit cell sizes, unit cell phases, or wall thicknesses. Wall thickness may be in a range from 80 to 100 μm, 100 to 120 μm, 120 to 140 μm, 140 to 160 μm, 160 to 200 μm, or greater than 200 μm. In some embodiments, the plurality of TPMS unit cells may be characterized by a gradient change in unit cell sizes or wall thicknesses. The TPMS cells may include functionally graded TPMS unit cells. Gradient changes may be in one or more directions and/or may be away from or toward the substrate. In some embodiments, the plurality of TPMS unit cells may include abrupt changes in unit cell size, wall thickness, and/or unit cell type.

The plurality of TPMS unit cells may be a first plurality of TPMS unit cells. The lattice may include a second plurality of TPMS unit cells. The second plurality of TPMS unit cells may have a different type surface than the first plurality of TPMS unit cells.

The second plurality of TPMS unit cells may be characterized by a different unit cell size than the first plurality of TPMS unit cells. The first plurality of TPMS unit cells may be disposed between the substrate and the second plurality of TPMS unit cells. The first plurality of TPMS unit cells may be characterized by a first unit cell size. The second plurality of TPMS unit cells may be characterized by a second unit cell size larger than the first unit cell size. Additional pluralities of TPMS unit cells may be present. The second plurality of TPMS unit cells may smoothly transition from the first plurality of TPMS unit cells. For example, the surface may be continuously differentiable between the two pluralities or between any two adjacent pluralities.

In some embodiments, the unit cell sizes may have a vertical gradient. Vertical may refer to a direction orthogonal to the substrate. The first plurality of TPMS unit cells may be disposed between the substrate and the second plurality of TPMS unit cells. The first plurality of TPMS unit cells may be characterized by a first unit cell size. The second plurality of TPMS unit cells may be characterized by a second unit cell size larger than the first unit cell size. In some embodiments, the second plurality of TPMS unit cells may be characterized by a second unit cell size smaller than the first unit cell size. The vertical gradient may be characterized by a gradient factor from 0.1 to 0.5, 0.5 to 1.0, 1.0 to 1.5, 1.5 to 2.0, or greater than 2.0.

In some embodiments, the unit cell sizes may have a horizontal gradient. Horizontal may refer to a direction parallel to the substrate. The substrate may have a first end and a second end. The second end may be opposite the first end along the first direction. The first end may be an upstream end (e.g., closer to upstream of configured flow). The first plurality of TPMS unit cells may be disposed closer to the first end than the second plurality of TPMS unit cells. In some embodiments, the first plurality of TPMS unit cells may be disposed closer to the second end than the second plurality of TPMS unit cells. In some embodiments, the second plurality of TPMS unit cells may be characterized by a second unit cell size larger than the first unit cell size. The horizontal gradient may be characterized by a gradient factor from 0.1 to 0.5, 0.5 to 1.0, 1.0 to 1.5, 1.5 to 2.0, or greater than 2.0.

In embodiments, the lattice may be in contact with a liquid and a gas. The gas may be present in nucleation sites on the lattice. The liquid may be water, coolants, or other refrigerants. The gas may be water vapor or vapor of at least a portion of the liquid. In embodiments, the lattice may be in contact with a liquid. The liquid may be at its boiling point temperature or within 1, 2, 3, 4, or 5 degrees Celsius of its boiling point temperature (e.g., 100° C. for water). Bubbles of the gas may be characterized by a diameter to unit cell size ratio in a range from 0.25 to 0.50, 0.50 to 0.75, 0.75 to 0.80, 0.80 to 0.90, 0.90 to 1.0, 1.0 to 1.1, 1.1 to 1.2, 1.2 to 1.25, 1.25 to 1.50, or greater than 1.50.

The cooling structure may be characterized by a critical heat flux in a range from 350 to 400 W/cm², 400 to 450 W/cm², 450 to 500 W/cm², 500 to 550 W/cm², 550 to 600 W/cm², 600 to 650 W/cm², 650 to 700 W/cm², 700 to 750 W/cm², 750 to 800 W/cm², or greater than 800 W/cm². The cooling structure may be characterized by a heat transfer coefficient in a range from 15 to 20 W/cm²·K, 20 to 25 W/cm²·K, 25 to 30 W/cm²·K, 30 to 35 W/cm²·K, or 35 to 40 W/cm²·K. The heat transfer coefficient may be for a heat flux of 350 to 400 W/cm², 400 to 450 W/cm², 450 to 500 W/cm², 500 to 550 W/cm², 550 to 600 W/cm², 600 to 650 W/cm², 650 to 700 W/cm², 700 to 750 W/cm², 750 to 800 W/cm², or greater than 800 W/cm².

The cooling structure may have a CoP in a range from 10,000 to 50,000, 50,000 to 100,000, 100,000 to 200,000, 200,000 to 300,000, 300,000 to 400,000, 400,000 to 500,000, 500,000 to 600,000, 600,000 to 700,000, 700,000 to 800,000, or over 800,000.

In some embodiments, the cooling structure may include a cover. The cover and the substrate may define a channel. The cover may be a plate. The cover may be any metal described herein. The cover may be configured similar to cover plate 1830 and/or quartz glass 1832. In some embodiments, the height of the lattice may be a fraction of the height of the channel, including 0.10 to 0.25, 0.25 to 0.50, 0.50 to 0.75, or 0.75 to 1.0.

Embodiments may include a plurality of cooling structures. Embodiments may include one or more processors. Embodiments may include one or more server blades. Embodiments may include a data center. The cooling structure may exclude moving parts (e.g., fan, impeller, blower) or any contact with moving parts.

### Example Cooling Systems

Example systems may include a system for cooling. The system may include a heat source. The heat source may be any heat source described herein.

The system may include a cooling structure, which may be any cooling structure described herein. The cooling structure may be in thermal communication with the heat source. The heat source may be a processor or any heat source described herein.

The system may include a liquid in contact with the cooling structure. The liquid may include water or be any liquid described herein.

In some embodiments, the system may also include a flow-inducing device operably coupled to the liquid. The flow-inducing device may force, directly or indirectly, the liquid to flow in a direction. The direction may be parallel or substantially parallel to the substrate. The flow may be through the lattice and/or a channel including the lattice. The flow-inducing device may be a pump, impeller, a gas-injection sparger, an eductor (jet pump), an airlift device (gas-lift pump), a paddle wheel or rotary flow generator, an Archimedes screw, a positive-displacement pump, a peristaltic pump, a pressurization source configured to create a pressure differential across the flow channel, an oscillatory or reciprocating flow driver, an electro-osmotic pump, or an ultrasonic/acoustic flow driver.

The system may further include a vessel containing the lattice and/or the liquid in contact with the cooling structure. The vessel may be for flow boiling heat transfer. The vessel may include parts of FIG. 18B or any vessel described herein. The vessel may include an inlet and an outlet. The inlet and outlet may be configured for colder liquid to flow in and warmer liquid-vapor mixture to flow out.

The system may include a cooling system in fluidic communication with the vessel via the outlet. The cooling system may cool the heated liquid-vapor so that the liquid can be recirculated to the cooling structure. The cooling system may include a heat exchanger, a condenser, a radiator, a cooling tower, or an evaporative system.

The system may include a liquid supply in fluidic communication with the vessel via the inlet. The liquid supply may be a reservoir, a tank, or a pressurized source (e.g., connection to municipal water or building water line).

In some embodiments, the system may include a closed-loop flow path (e.g., a flow loop) configured to circulate the liquid to and from the cooling structure. The flow loop may include the liquid supply, one or more flow conduits fluidically coupling the liquid supply to the cooling structure, and/or a return line configured to return heated liquid-vapor mixture from the cooling structure to the liquid supply for recirculation. The flow loop may further include the inlet and the outlet associated with a flow channel that contains the cooling structure, such that liquid flows through the channel during flow boiling heat transfer.

In some embodiments, the system may include a pump or other flow driver fluidically coupled to the flow loop and configured to circulate the liquid through the cooling structure. The pump may be a gear pump or any other pump described herein, and may be controllable (e.g., variable speed) to set a target flow rate through the channel and/or through internal passages of the lattice.

In some embodiments, the system may include a flow sensor configured to monitor a flow rate of the liquid in the flow loop. The flow sensor may include a flow meter disposed upstream or downstream of the cooling structure. The flow sensor may be in communication with a controller configured to display, store, and/or regulate the flow rate (e.g., by adjusting operation of the pump).

The system may include a temperature sensor in thermal communication with the liquid, the cooling structure, or the heat source. The temperature sensor may be a thermocouple or any suitable temperature sensor. The temperature sensor may be in communication with a computer, which can monitor, display, and store temperature data.

In some embodiments, the system may include one or more fluid-conditioning components disposed in the flow loop upstream of the cooling structure. For example, the system may include a filter (e.g., a microfilter) configured to remove particulates and/or impurities from the liquid. Additionally or alternatively, the system may include a temperature-conditioning device configured to control an inlet liquid temperature and/or subcooling relative to a saturation temperature, such as a thermostatic bath, heater, chiller, or heat exchanger.

In some embodiments, the system may include a vessel. The vessel may be for pool boiling heat transfer. The vessel may include the lattice, the heat source, and the cooling structure. The vessel may also contain the liquid. The vessel may include vessel 1704 or any vessel described herein. The vessel may include a condenser configured to convert vapor to liquid for reuse with pool boiling heat transfer. The condenser may include a coolant or refrigerant. The condenser may be in communication with a cooling system, which may cool the coolant or refrigerant for recirculation. The cooling system may be any cooling system described herein.

In some embodiments, the system may include one or more pressure sensors configured to measure pressure at one or more locations in the flow loop. For example, the system may include an inlet pressure sensor and an outlet pressure sensor coupled to corresponding ports of a flow channel containing the cooling structure, thereby enabling determination of a pressure drop across the cooling structure and/or across the channel.

In some embodiments, the system may include a controller in communication with one or more of the flow sensor and the pressure sensors. The controller may be configured to determine a pumping power based on measured pressure drop and flow rate, and may further be configured to determine a coefficient of performance (CoP) for the cooling system based on a heat removal rate relative to the pumping power. The controller may further be configured to control operation of the pump, the temperature-conditioning device, and/or other components to achieve a target thermal performance, pressure drop, and/or CoP.

In some embodiments, the system may include an optical monitoring arrangement configured to observe boiling behavior at the cooling structure. The system may include a transparent wall or window (e.g., a transparent cover, chamber wall, or viewing port) providing optical access to the cooling structure and/or to a flow channel containing the cooling structure. The optical monitoring arrangement may include an imaging device (e.g., a camera, including a high-speed camera and/or microscope optics) and, optionally, an illumination source configured to improve image quality for observing bubble dynamics and/or two-phase flow patterns.

### Example Methods

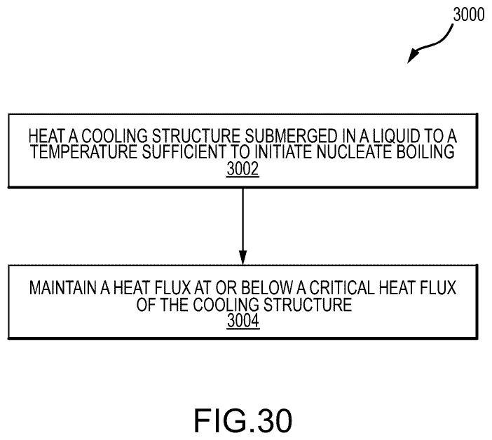

FIG. 30 illustrates a method 3000 of cooling. In block 3002, method 3000 heats a cooling structure submerged in a liquid to a temperature sufficient to initiate nucleate boiling, wherein vapor forms at nucleation sites on the heated surface, wherein the cooling structure is any cooling structure described herein.

In block 3004, method 3000 maintains a heat flux at or below a critical heat flux of the cooling structure. The heat flux may be maintained by adjusting processor load, condenser parameters, and/or other cooling mechanisms. The heat flux may be produced from any heat source described herein.

The liquid may be subject to convective flow. The gas may move as a result of buoyancy and/or may move as a result of convective flow. In some embodiments, the liquid may be agitated (e.g., stirred). The liquid may be held in a container (e.g., vessel 1704), where there is no flow of liquid or related gas into or out of the container. Method 3000 may be performed by a control system.

In some embodiments, method 3000 may include flowing the liquid and vapor through the lattice and out of the lattice. Flowing the liquid may be for flow boiling heat transfer, which may use any flow-inducing device described herein. The liquid may be flowed at a flowrate from 50 to 100 mL/min, 100 to 200 mL/min, 200 to 300 mL/min, or over 300 mL/min. In some embodiments, the flow may be laminar. In some embodiments, the flow may be turbulent.

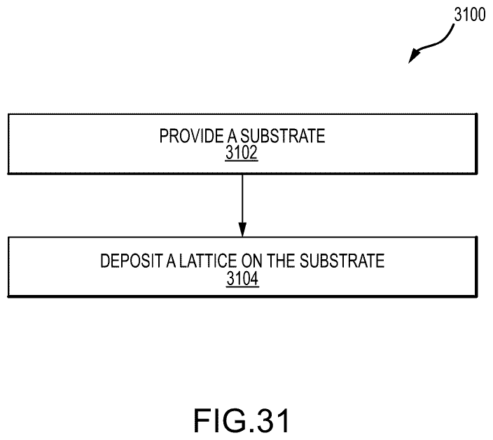

FIG. 31 shows a method of manufacturing a cooling structure. The cooling structure may be any cooling structure described herein, including structure 100 or those of FIG. 4A, FIG. 4B, FIG. 4C, FIG. 9, or FIG. 12.

In block 3102, method 3100 provides a substrate. The substrate may be configured to be a fixed heat source during operation. The substrate may be a processor. For example, the processor may be a neural processor, an artificial intelligence (AI) accelerator, a complex instruction set computer (CISC) microprocessor, a reduced instruction set computer (RISC) microprocessor, a microcontroller, a digital signal processor, a system-on-chip (SOC), a field-programmable gate array (FPGA), or very long instruction word (VLIW). As used herein, the microprocessor may include packaging surrounding the integrated circuits manufactured by semiconductor processing techniques.

In block 3104, method 3100 deposits a lattice on the substrate. The lattice may include a plurality of triply periodic minimal surface (TPMS) unit cells, and wherein the TPMS unit cells comprise surfaces that are periodic in a first direction, a second direction, and a third direction. The lattice may be any lattice described herein, including lattice 102. The lattice may be deposited by additive manufacturing, including by electrochemical additive manufacturing.

In some embodiments, the lattice may be deposited by laser powder bed fusion (LPBF). For example, method 3100 may include providing a powder bed including metal powder, selectively melting the metal powder with a laser to form successive layers of the lattice, and repeating the selective melting to build the lattice layer-by-layer. In some embodiments, the lattice is formed directly on the substrate by LPBF. In some embodiments, the lattice is formed separately by LPBF and subsequently attached to the substrate and/or a heat source.

In some embodiments, the method may include bonding the lattice using thermal interface materials to the substrate instead of depositing the lattice on the substrate. In some embodiments, the method may include attaching any cooling structure described herein to a fixed heat source. The manufactured cooling structure may be used for pool boiling heat transfer.

In some embodiments, the substrate provided in block 3102 may be a body configured to be placed in thermal communication with a heat source during operation, rather than being the heat source itself. The substrate may be a metal plate or other metal component. After depositing the lattice on the substrate, method 3100 may include attaching the substrate to a fixed heat source (e.g., a processor package or housing) by soldering, brazing, diffusion bonding, welding, clamping, adhesives, and/or thermal interface materials, such that heat from the heat source is conducted through the substrate to the lattice during operation.

Any of the methods described herein may be totally or partially performed with a computer system including one or more processors, which can be configured to perform the steps. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order that is logically possible. Additionally, portions of these steps may be used with portions of other steps from other methods. Also, all or portions of a step may be optional. Additionally, any of the steps of any of the methods can be performed with modules, units, circuits, or other means of a system for performing these steps.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

The above description of example embodiments of the present disclosure has been presented for the purposes of illustration and description and are set forth so as to provide those of ordinary skill in the art with a complete disclosure and description of how to make and use embodiments of the present disclosure. It is not intended to be exhaustive or to limit the disclosure to the precise form described nor are they intended to represent that the experiments are all or the only experiments performed. Although the disclosure has been described in some detail by way of illustration and example for purposes of clarity of understanding, it is readily apparent to those of ordinary skill in the art in light of the teachings of this disclosure that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the disclosure being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

A recitation of “a”, “an” or “the” is intended to mean “one or more” unless specifically indicated to the contrary. The use of “or” is intended to mean an “inclusive or,” and not an “exclusive or” unless specifically indicated to the contrary. Reference to a “first” component does not necessarily require that a second component be provided. Moreover, reference to a “first” or a “second” component does not limit the referenced component to a particular location unless expressly stated. The term “based on” is intended to mean “based at least in part on.”

The claims may be drafted to exclude any element which may be optional. As such, this statement is intended to serve as antecedent basis for use of such exclusive terminology as “solely”, “only”, and the like in connection with the recitation of claim elements, or the use of a “negative” limitation.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within embodiments of the present disclosure. The upper and lower limits of these smaller ranges may independently be included or excluded in the range, and each range where either, neither, or both limits are included in the smaller ranges is also encompassed within the present disclosure, subject to any specifically excluded limit in the stated range. Where the stated range includes one or both of the limits, ranges excluding either or both of those included limits are also included in the present disclosure.

All patents, patent applications, publications, and descriptions mentioned herein are hereby incorporated by reference in their entirety for all purposes as if each individual publication or patent were specifically and individually indicated to be incorporated by reference and are incorporated herein by reference to disclose and describe the methods and/or materials in connection with which the publications are cited. None is admitted to be prior art.

Embodiments may include the following or any combination thereof.

Embodiment 1. A cooling structure for boiling heat transfer, the cooling structure comprising: a substrate, wherein the substrate is a fixed heat source or configured to be in thermal communication with the fixed heat source; and a lattice disposed on the substrate, wherein the lattice comprises a plurality of triply periodic minimal surface (TPMS) unit cells, and wherein the TPMS unit cells comprise surfaces that are periodic in a first direction, a second direction, and a third direction.

Embodiment 2. The cooling structure of embodiment 1, wherein the substrate is soldered to the fixed heat source.

Embodiment 3. The cooling structure of embodiment 1, wherein the fixed heat source is a processor.

Embodiment 4. The cooling structure of embodiment 1, wherein: the lattice contacts a surface of the substrate; the surface is characterized by a substrate length in the first direction and a substrate width in the second direction; the lattice is characterized by a lattice height in the third direction; and the lattice height is less than the substrate length and is less than the substrate width.

Embodiment 5. The cooling structure of embodiment 1, wherein: the lattice is characterized by a height orthogonal to a surface of the substrate, a TPMS unit cell of the plurality of TPMS unit cells is characterized by a unit cell size, and the height is less than the unit cell size.

Embodiment 6. The cooling structure of embodiment 5, wherein the height is in a range from 0.5 to 5 mm.

Embodiment 7. The cooling structure of embodiment 1, wherein: the lattice is characterized by a height orthogonal to a surface of the substrate, a TPMS unit cell of the plurality of TPMS unit cells is characterized by a unit cell size, and a ratio of the height to the unit cell size is in a range from 0.5 to 5.

Embodiment 8. The cooling structure of embodiment 1, wherein: a TPMS unit cell of the plurality of TPMS unit cells is characterized by a unit cell size, and the unit cell size is in a range from 1 to 4 mm.

Embodiment 9. The cooling structure of embodiment 1, wherein the plurality of TPMS unit cells comprises P-type TPMS unit cells, G-type TPMS unit cells, D-type TPMS unit cells, or any blend thereof.

Embodiment 10. The cooling structure of embodiment 1, wherein the lattice is formed by additive manufacturing.

Embodiment 11. The cooling structure of embodiment 1, wherein the lattice comprises a metal.

Embodiment 12. The cooling structure of embodiment 11, wherein the metal comprises copper.

Embodiment 13. The cooling structure of embodiment 1, wherein the plurality of TPMS unit cells comprises identical TPMS unit cells.

Embodiment 14. The cooling structure of embodiment 1, wherein the plurality of TPMS unit cells comprises TPMS unit cells of different TPMS unit cell types.

Embodiment 15. The cooling structure of embodiment 1, wherein the plurality of TPMS unit cells comprises TPMS unit cells characterized by different unit cell sizes or wall thicknesses.

Embodiment 16. The cooling structure of embodiment 1, wherein the lattice is in contact with a liquid and a gas.

Embodiment 17. The cooling structure of embodiment 16, wherein the gas is in present at nucleation sites on the lattice.

Embodiment 18. The cooling structure of embodiment 16, wherein the liquid is water, and the gas is water vapor.

Embodiment 19. The cooling structure of embodiment 16, wherein the liquid is characterized by a flowrate through the lattice in a direction parallel to the substrate.

Embodiment 20. The cooling structure of embodiment 1, wherein the cooling structure is characterized by a critical heat flux in a range from 250 to 1100 W/cm² for water at atmospheric pressure.

Embodiment 21. The cooling structure of embodiment 1, wherein the cooling structure is characterized by a heat transfer coefficient in a range from 10 to 35 W/cm²K for water at atmospheric pressure.

Embodiment 22. The cooling structure of embodiment 1, wherein the substrate is configured to be impervious to a liquid.

Embodiment 23. The cooling structure of embodiment 1, further comprising: a cover, wherein the cover and the substrate define a channel with the lattice disposed within the channel.

Embodiment 24. The cooling structure of embodiment 1, wherein: the plurality of TPMS unit cells is a first plurality of TPMS unit cells, and the lattice comprises a second plurality of TPMS unit cells characterized by a different unit cell size than the first plurality of TPMS unit cells.

Embodiment 25. The cooling structure of embodiment 24, wherein: the first plurality of TPMS unit cells is disposed between the substrate and the second plurality of TPMS unit cells, the first plurality of TPMS unit cells is characterized by a first unit cell size, and the second plurality of TPMS unit cells is characterized by a second unit cell size larger than the first unit cell size.

Embodiment 26. The cooling structure of embodiment 24, wherein: the substrate has a first end and a second end, the second end is opposite the first end along the first direction, and the first plurality of TPMS unit cells is disposed closer to the first end than the second plurality of TPMS unit cells.

Embodiment 27. A system for cooling, the system comprising: a heat source; the cooling structure of embodiment 1, wherein the cooling structure is in thermal communication with the heat source; and a liquid in contact with the cooling structure.

Embodiment 28. The system of embodiment 27, further comprising: a flow-inducing device operably coupled to the liquid.

Embodiment 29. The system of embodiment 28, wherein the flow-inducing device is a pump, an impeller, or a gas-injection sparger.

Embodiment 30. The system of embodiment 27, further comprising: a vessel containing the lattice and the liquid in contact with the cooling structure, wherein: the vessel comprises an inlet and an outlet.

Embodiment 31. The system of embodiment 30, further comprising: a cooling system in fluidic communication with the vessel via the outlet, and a liquid supply in fluidic communication with the vessel via the inlet.

Embodiment 32. The system of embodiment 27, wherein the heat source is a processor.

Embodiment 33. The system of embodiment 27, further comprising: a vessel containing the lattice, the heat source, and the cooling structure, and a condenser disposed in the vessel.

Embodiment 34. A method of cooling, the method comprising: heating a cooling structure submerged in a liquid to a temperature sufficient to initiate nucleate boiling, wherein vapor forms at nucleation sites on a heated surface of the cooling structure, wherein the cooling structure is the cooling structure of embodiment 1; and maintaining a heat flux at or below a critical heat flux of the cooling structure.

Embodiment 35. The method of embodiment 34, further comprising: flowing the liquid and vapor through the lattice and out of the lattice.

Embodiment 36. A method of manufacturing a cooling structure, the method comprising: providing a substrate, wherein the substrate is configured to be a fixed heat source during operation; and depositing a lattice on the substrate, wherein the lattice comprises a plurality of triply periodic minimal surface (TPMS) unit cells, and wherein the TPMS unit cells comprise surfaces that are periodic in a first direction, a second direction, and a third direction.

Embodiment 37. The method of embodiment 36, wherein the substrate is a processor.

Embodiment 38. The method of embodiment 36, wherein depositing the lattice on the substrate comprises electrochemical additive manufacturing.

What is claimed is:

1. A cooling structure for boiling heat transfer, the cooling structure comprising:
a substrate, wherein the substrate is a fixed heat source or configured to be in thermal communication with the fixed heat source; and
a lattice disposed on the substrate, wherein the lattice comprises a plurality of triply periodic minimal surface (TPMS) unit cells, and wherein the TPMS unit cells comprise surfaces that are periodic in a first direction, a second direction, and a third direction.

2. The cooling structure of claim 1, wherein the substrate is soldered to the fixed heat source.

3. The cooling structure of claim 1, wherein the fixed heat source is a processor.

4. The cooling structure of claim 1, wherein:
the lattice contacts a surface of the substrate;
the surface is characterized by a substrate length in the first direction and a substrate width in the second direction;
the lattice is characterized by a lattice height in the third direction; and
the lattice height is less than the substrate length and is less than the substrate width.

5. The cooling structure of claim 1, wherein:
the lattice is characterized by a height orthogonal to a surface of the substrate,
a TPMS unit cell of the plurality of TPMS unit cells is characterized by a unit cell size, and
the height is less than the unit cell size.

6. The cooling structure of claim 5, wherein the height is in a range from 0.5 to 5 mm.

7. The cooling structure of claim 1, wherein:
the lattice is characterized by a height orthogonal to a surface of the substrate,
a TPMS unit cell of the plurality of TPMS unit cells is characterized by a unit cell size, and
a ratio of the height to the unit cell size is in a range from 0.5 to 5.

8. The cooling structure of claim 1, wherein:
a TPMS unit cell of the plurality of TPMS unit cells is characterized by a unit cell size, and
the unit cell size is in a range from 1 to 4 mm.

9. The cooling structure of claim 1, wherein the plurality of TPMS unit cells comprises P-type TPMS unit cells, G-type TPMS unit cells, D-type TPMS unit cells, or any blend thereof.

10. The cooling structure of claim 1, wherein the lattice comprises copper.

11. The cooling structure of claim 1, wherein the plurality of TPMS unit cells comprises identical TPMS unit cells.

12. The cooling structure of claim 1, wherein the plurality of TPMS unit cells comprises TPMS unit cells of different TPMS unit cell types.

13. The cooling structure of claim 1, wherein the lattice is in contact with a liquid and a gas.

14. The cooling structure of claim 13, wherein the gas is present at nucleation sites on the lattice.

15. The cooling structure of claim 13, wherein the liquid is water, and the gas is water vapor.

16. The cooling structure of claim 13, wherein the liquid is characterized by a flowrate through the lattice in a direction parallel to the substrate.

17. The cooling structure of claim 1, wherein the cooling structure is characterized by a critical heat flux in a range from 250 to 1100 W/cm² for water at atmospheric pressure.

18. The cooling structure of claim 1, wherein the cooling structure is characterized by a heat transfer coefficient in a range from 10 to 35 W/cm²K for water at atmospheric pressure.

19. The cooling structure of claim 1, further comprising:
a cover, wherein the cover and the substrate define a channel with the lattice disposed within the channel.

20. The cooling structure of claim 1, wherein:
the plurality of TPMS unit cells is a first plurality of TPMS unit cells, and
the lattice comprises a second plurality of TPMS unit cells characterized by a different unit cell size than the first plurality of TPMS unit cells.

21. The cooling structure of claim 20, wherein:
the first plurality of TPMS unit cells is disposed between the substrate and the second plurality of TPMS unit cells,
the first plurality of TPMS unit cells is characterized by a first unit cell size, and
the second plurality of TPMS unit cells is characterized by a second unit cell size larger than the first unit cell size.

22. The cooling structure of claim 20, wherein:
the substrate has a first end and a second end,
the second end is opposite the first end along the first direction, and
the first plurality of TPMS unit cells is disposed closer to the first end than the second plurality of TPMS unit cells.

23. A system for cooling, the system comprising:
a heat source;
a cooling structure comprising:
a substrate, wherein the substrate is in thermal communication with a fixed heat source; and
a lattice disposed on the substrate, wherein the lattice comprises a plurality of triply periodic minimal surface (TPMS) unit cells, and wherein the TPMS unit cells comprise surfaces that are periodic in a first direction, a second direction, and a third direction; and
a liquid in contact with the cooling structure.

24. The system of claim 23, further comprising:
a flow-inducing device operably coupled to the liquid.

25. The system of claim 23, further comprising:
a vessel containing the lattice and the liquid in contact with the cooling structure,
wherein:
the vessel comprises an inlet and an outlet.

26. The system of claim 25, further comprising:
a cooling system in fluidic communication with the vessel via the outlet, and
a liquid supply in fluidic communication with the vessel via the inlet.

27. The system of claim 23, further comprising:
a vessel containing the lattice, the heat source, and the cooling structure, and
a condenser disposed in the vessel.
